(19) United States
(12) Patent Application Publication
(10) Pub. No.: US 2024/0379903 A1
(43) Pub. Date: Nov. 14, 2024

(54) INFRARED LED ELEMENT

(71) Applicant: Ushio Denki Kabushiki Kaisha, Tokyo (JP)

(72) Inventors: Kuniaki ISHIHARA, Tokyo (JP); Nobuhiro FUKUMOTO, Tokyo (JP)

(73) Assignee: Ushio Denki Kabushiki Kaisha, Tokyo (JP)

(21) Appl. No.: 18/690,978

(22) PCT Filed: Mar. 24, 2022
(86) PCT No.: PCT/JP2022/014093

§ 371 Date: Mar. 11, 2024

(30) Foreign Application Priority Data
Sep. 13, 2021 (JP) 2021-148564

(51) Int. Cl. H01L 33/20; H01L 33/00; H01L 33/30; H01L 33/44

(52) U.S. Cl. CPC H01L 33/20; H01L 33/0062; H01L 33/30; H01L 33/44

(57) ABSTRACT

An infrared LED element includes: an InP substrate that has a first principal surface and a second principal surface; a first semiconductor layer formed on or over the first principal surface of the InP substrate; an active layer formed on or over the first semiconductor layer; a second semiconductor layer formed on or over the active layer; a first electrode formed on or over the first semiconductor layer in a region in which the active layer is not formed; a second electrode formed on or over the second semiconductor layer at a position apart from the first electrode in a direction parallel to the first principal surface of the InP substrate; and a relief portion formed on the second principal surface of the InP substrate and having periodicity in a direction parallel to the second principal surface.

### TECHNICAL FIELD

The present invention relates to an infrared LED element, and particularly relates to an infrared LED element that can emit infrared light having a peak emission wavelength of 1000 nm to 1800 nm.

### BACKGROUND ART

In recent years, semiconductor light-emitting elements having an emission wavelength in an infrared region of wavelengths of 1000 nm or more have been used for a wide variety of applications such as surveillance or monitoring cameras, gas detectors, medical sensors, and industrial equipment.

A semiconductor light-emitting element having an emission wavelength of 1000 nm or more is generally manufactured through the following procedure. A semiconductor layer of a first conductivity type, an active layer (sometimes referred to as an “emission layer”), and a semiconductor layer of a second conductivity type are epitaxially grown in sequence on an indium phosphide (InP) substrate that acts as a growth substrate. Then, an electrode for electric current injection is formed on a semiconductor wafer, and the semiconductor wafer is cut into a chip. In this manner, the semiconductor light-emitting element is manufactured.

Previously, in terms of a semiconductor light-emitting element having a peak emission wavelength of 1000 nm or more, semiconductor laser elements have been developed ahead of other semiconductor light-emitting elements. Meanwhile, the development of LED elements has not been advanced compared to laser elements because of very few applications of LED elements.

However, in recent years, in response to expansion of the range of applications, demand for infrared LED elements with improved light output has been growing. For example, Patent Document 1 discloses an infrared LED element that includes: a wafer having, on an InP substrate, an LED structure that is obtained by crystal growth; and electrodes formed on upper and lower surfaces of the wafer, the infrared LED element emitting light by electric current injected into an active layer by application of voltage across both electrodes. Further, Patent Document 2 discloses a structure having improved light extraction efficiency by bonding a wafer that has an epitaxial layer formed by crystal growth on a growth substrate to a conductive support substrate, and then, removing the growth substrate.

### PRIOR ART DOCUMENTS

### Patent Documents

Patent Document 1: JP-A-H4-282875
Patent Document 2: JP-A-2013-30606
Patent Document 3: JP-A-2000-114595

### SUMMARY OF THE INVENTION

### Problems to be Solved by the Invention

The LED element disclosed in Patent Document 2 needs a step for bonding a support substrate different from the growth substrate and a step for removing the growth substrate during manufacture, and thus has a complicated manufacturing process. Hence, in order to provide an LED element by a simple method, it is preferable to use the growth substrate as it is as indicated in, for example, Patent Document 1.

However, in the structure in Patent Document 1, the electrode is disposed on a surface (hereinafter referred to as a “back surface”) opposite to a side of the InP substrate on which the epitaxial layer is formed, and thus, the structure needs to pass an electric current through the InP substrate. Thus, the InP substrate is designed to have conductivity by being doped with a dopant in high concentration.

The LED element in Patent Document 1 is planned to extract infrared light generated in the active layer from the side opposite to the InP substrate. Meanwhile, infrared light emitted from the active layer also travels to the InP substrate side. When the InP substrate is doped with a dopant in high concentration, infrared light is absorbed by free carriers present in the InP substrate. As a result, even if the electrode disposed on the back surface of the InP substrate is made of a reflective material, infrared light is absorbed inside the InP substrate whenever the infrared light passes through the InP substrate. This prevents the attainment of high light extraction efficiency.

From such a viewpoint, the present inventor has studied a structure of extracting light from an InP substrate side in an infrared LED element in which an InP substrate as a growth substrate is not removed. In such a structure, it is not necessary that the InP substrate has conductivity. Therefore, a problem of absorption of infrared light by free carriers present in the InP substrate is less likely to occur.

In particular, in recent years, the range of applications of infrared LED elements having a peak emission wavelength of 1000 nm or more has been expanded as described above. From such a background, it is predicted that there is an increase in demand for a small and low-profile infrared LED element having a peak emission wavelength of 1000 nm or more and having high light emission efficiency.

As a small and low-profile LED element, a mounting method called a flip chip that does not require a wire bonding process is known (see, for example, Patent Document 3). Patent Document 3 relates to a GaN-based LED element. At the filing date of the present application, a structure in which a flip-chip method is adopted in an InP-based infrared LED element having a peak emission wavelength of 1000 nm or more is not common. This is because, as described above, there are few applications of LED elements having a peak emission wavelength of 1000 nm or more in the first place, and the development thereof has not been advanced. For this reason, the problem of the infrared LED element including the InP substrate and using the flip-chip method has not been known.

As a result of intensive studies, the present inventor has newly found a problem that high light extraction efficiency cannot be obtained when a flip-chip method is adopted in an infrared LED element having a peak emission wavelength exceeding 1000 nm.

In view of the above problem, an object of the present invention is to improve light extraction efficiency in an infrared LED element having a peak emission wavelength exceeding 1000 nm.

### Means for Solving the Problems

In a flip-chip infrared LED element including an InP substrate, infrared light generated in an active layer propagates through an epitaxial layer formed on or over the InP substrate and the inside of the InP substrate, and then is extracted to the outside from a principal surface (back surface) or a lateral surface of the InP substrate. Here, when infrared light having a wavelength of 1000 nm to 1800 nm is used as a reference, the refractive index of air is 1, and the refractive index of resin is about 1.2 to 1.6, whereas the refractive index of InP is as large as about 3.1 to 3.3. That is, there is a large difference in refractive index at the interface of the InP substrate.

Since there is a relatively large difference in refractive index, at least a part of the infrared light traveling from the active layer toward the light extraction surface of the InP substrate is totally reflected on the light extraction surface. For example, when air is present outside of the InP substrate (in other words, in a case where the principal surface of the InP substrate is in contact with air), about 98% of infrared light generated in the active layer is totally reflected on the light extraction surface and confined inside the LED element.

In a field of an LED element having a wavelength different from that of an InP-based LED element, such as a GaN-based or GaAs-based LED element, a technique of roughening a light extraction surface is known as a method for reducing an amount of totally reflected light. However, it has been confirmed as a result of intensive studies by the present inventor that, in the case of an InP-based LED element having a longer wavelength than that of a GaN-based or GaAs-based LED element, the effect of enhancing the light extraction efficiency is extremely limited even when a random rough surface is formed on the principal surface of the InP substrate by polishing. In other words, the present inventor has newly found that there is still room for improving the light extraction efficiency in the InP-based infrared LED element.

An infrared LED element according to the present invention has a peak emission wavelength in a range from 1000 nm to 1800 nm and includes: an indium phosphide (InP) substrate that has a first principal surface and a second principal surface which are a pair of principal surfaces facing each other;
a first semiconductor layer of a p-type or an n-type, the first semiconductor layer being formed on or over the first principal surface of the InP substrate;
an active layer formed on or over the first semiconductor layer;
a second semiconductor layer of a conductivity type different from the conductivity type of the first semiconductor layer, the second semiconductor layer being formed on or over the active layer:
a first electrode formed on or over the first semiconductor layer in a region in which the active layer is not formed;
a second electrode formed on or over the second semiconductor layer at a position apart from the first electrode in a direction parallel to the first principal surface of the InP substrate; and
a relief portion formed on the second principal surface of the InP substrate and having periodicity in a direction parallel to the second principal surface.

According to the above configuration, the relief portion having a periodicity in a direction parallel to the surface (second principal surface) of the InP substrate, that is, having a two-dimensional periodicity, is formed on the principal surface, whereby the light extraction efficiency is improved as compared with a case where a random rough surface is formed on the principal surface of the InP substrate. This will be described in detail later in the section “MODE FOR CARRYING OUT THE INVENTION”.

The relief portion preferably satisfies Math Expression (1) and Math Expression (2) where the peak emission wavelength is λ [μm], the refractive index of the InP substrate is n, a period length which is a distance between adjacent protrusions or recesses is a [μm], and the depth of the recess is d [μm].

$$a > 7.2 \times ( λ / n ) \qquad ( 1 )$$

$$d > m \times ( a - 10 ) + 3.5 \qquad ( 2 )$$

Here, m is a dimensionless value defined by the following math expression.

$$m = - 1.02 \times ( λ / n ) + 0.602$$

The period length a [μm] and the depth d [μm] preferably further satisfy Math Expressions (3) and (4).

$$a > 10 \times ( λ / n ) \qquad ( 3 )$$

$$p \times ( a - 10 ) + 5. < d < q \times ( a - 8. ) + 8. \qquad ( 4 )$$

Here, p and q are dimensionless values defined by the following math expressions, respectively.

$$p = - 1.01 \times ( λ / n ) + 0.727$$

$$q = - 3.91 \times ( λ / n ) + 2.09$$

The infrared LED element may include a translucent layer on the upper surface of the relief portion, the translucent layer being made of a material that exhibits transparency to infrared light emitted from the active layer and that has a refractive index between a refractive index of a material constituting the InP substrate and a refractive index of air.

More preferably, the translucent layer has a transmittance of 80% or more with respect to infrared light. Specifically, one kind or two or more kinds belonging to the group consisting of SiO₂, SiON, SIN, TiO₂, and MgO can be used as the material of the translucent layer.

The InP substrate may be doped with Fe.

By doping the InP substrate with Fe, a deep level is formed in the InP substrate, and as a result, the InP substrate exhibits semi-insulating properties. In the present specification, having “semi-insulating properties” means that a carrier concentration is less than 1×10¹⁷/cm³. In this case, the substrate has a resistivity of greater than or equal to 0.1 Ω·cm. On the other hand, a substrate being conductive means that the substrate has a carrier concentration greater than or equal to 1×10¹⁷/cm³ by use of a dopant atom forming a donor or an acceptor. In this case, the substrate has a resistivity of less than 0.01 Ω·cm.

Since the InP substrate exhibits semi-insulating properties, there are almost no free carriers in the InP substrate even during energization. Thus, when infrared light emitted from the active layer passes through the InP substrate, absorption of the infrared light by free carriers is less likely to occur inside the InP substrate. Consequently, an amount of infrared light absorbed by the InP substrate during propagation through the InP substrate is suppressed, whereby the light extraction efficiency is enhanced.

In the above-described infrared LED element, the first electrode and the second electrode are formed on the same surface side (first principal surface side) of the InP substrate, and thus, it is not necessary to pass an electric current into the active layer through the InP substrate during energization. This makes it possible to inject an electric current into the active layer even when the InP substrate is semi-insulating.

Note that, due to low mechanical rigidity, the InP substrate may be cracked or separated when being excessively reduced in thickness. For this reason, the thickness of the InP substrate is preferably greater than or equal to 20 μm. Note that the thickness of the InP substrate is preferably less than or equal to 1000 μm, considering that an excessive increase in thickness leads to an excessive increase in thickness (height) of the infrared LED element.

### Effect of the Invention

The present invention can provide an infrared LED element having a peak emission wavelength exceeding 1000 nm, the infrared LED element having high light extraction efficiency with a small and low-profile structure.

### BRIEF DESCRIPTION OF THE DRAWINGS

FIG. 1 is a cross-sectional view schematically illustrating a structure of an infrared LED element according to an embodiment.

FIG. 2 is a cross-sectional view of the infrared LED element illustrated in FIG. 1 from which some elements are removed, the infrared LED element in FIG. 2 being upside down with respect to FIG. 1.

FIG. 3 is a schematic plan view of the infrared LED element illustrated in FIG. 2 as viewed from the side opposite to an InP substrate.

FIG. 4 is an enlarged schematic cross-sectional view of a part of a region of the InP substrate where a relief portion is formed.

FIG. 5 is a schematic plan view of the region of the InP substrate where the relief portion is formed as viewed in a normal direction of a principal surface of the InP substrate.

FIG. 6A is a cross-sectional view for describing one step in a method for manufacturing the infrared LED element illustrated in FIG. 1.

FIG. 6B is a cross-sectional view for describing one step in the method for manufacturing the infrared LED element illustrated in FIG. 1.

FIG. 6C is a cross-sectional view for describing one step in the method for manufacturing the infrared LED element illustrated in FIG. 1.

FIG. 6D is a cross-sectional view for describing one step in the method for manufacturing the infrared LED element illustrated in FIG. 1.

FIG. 6E is a cross-sectional view for describing one step in the method for manufacturing the infrared LED element illustrated in FIG. 1.

FIG. 6F is a cross-sectional view for describing one step in the method for manufacturing the infrared LED element illustrated in FIG. 1.

FIG. 6G is a cross-sectional view for describing one step in the method for manufacturing the infrared LED element illustrated in FIG. 1.

FIG. 6H is a cross-sectional view for describing one step in the method for manufacturing the infrared LED element illustrated in FIG. 1.

FIG. 7 is an enlarged schematic cross-sectional view of a part of the region of the InP substrate where the relief portion is formed, FIG. 7 including elements necessary for describing simulation conditions.

FIG. 8 is a schematic plan view of the region of the InP substrate where the relief portion is formed as viewed in the normal direction of the principal surface of the InP substrate, FIG. 8 including elements necessary for describing simulation conditions.

FIG. 9A is a graph indicating a simulation calculation result regarding transmittance when infrared light L having a wavelength of 1050 nm is incident on the relief portion, the simulation calculation result being illustrated as distribution information with respect to a period length of the relief portion and a depth of a recess.

FIG. 9B is a graph indicating a simulation calculation result regarding transmittance when infrared light L having a wavelength of 1150 nm is incident on the relief portion, the simulation calculation result being illustrated as distribution information with respect to a period length of the relief portion and a depth of a recess.

FIG. 9C is a graph indicating a simulation calculation result regarding transmittance when infrared light L having a wavelength of 1250 nm is incident on the relief portion, the simulation calculation result being illustrated as distribution information with respect to a period length of the relief portion and a depth of a recess.

FIG. 9D is a graph indicating a simulation calculation result regarding transmittance when infrared light L having a wavelength of 1350 nm is incident on the relief portion, the simulation calculation result being illustrated as distribution information with respect to a period length of the relief portion and a depth of a recess.

FIG. 9E is a graph indicating a simulation calculation result regarding transmittance when infrared light L having a wavelength of 1450 nm is incident on the relief portion, the simulation calculation result being illustrated as distribution information with respect to a period length of the relief portion and a depth of a recess.

FIG. 9F is a graph indicating a simulation calculation result regarding transmittance when infrared light L having a wavelength of 1550 nm is incident on the relief portion, the simulation calculation result being illustrated as distribution information with respect to a period length of the relief portion and a depth of a recess.

FIG. 9G is a graph indicating a simulation calculation result regarding transmittance when infrared light L having a wavelength of 1650 nm is incident on the relief portion, the simulation calculation result being illustrated as distribution information with respect to a period length of the relief portion and a depth of a recess.

FIG. 10A is a graph indicating the result of FIG. 9B as a contour chart.

FIG. 10B is a graph indicating the result of FIG. 9F as a contour chart.

FIG. 11 is a graph indicating an approximate curve used to determine the value of m in Math Expression (2).

FIG. 12A is a graph in which a region indicating T(a, d)>3 is hatched for the result of FIG. 9A.

FIG. 12B is a graph in which a region indicating T(a, d)>3 is hatched for the result of FIG. 9B.

FIG. 12C is a graph in which a region indicating T(a, d)>3 is hatched for the result of FIG. 9C.

FIG. 12D is a graph in which a region indicating T(a, d)>3 is hatched for the result of FIG. 9D.

FIG. 12E is a graph in which a region indicating T(a, d)>3 is hatched for the result of FIG. 9E.

FIG. 12F is a graph in which a region indicating T(a, d)>3 is hatched for the result of FIG. 9F.

FIG. 12G is a graph in which a region indicating T(a, d)>3 is hatched for the result of FIG. 9G.

FIG. 13 is a graph indicating an approximate curve used to determine the value of q in Math Expression (4).

FIG. 14 is a schematic cross-sectional view for describing a structure of a stem used to measure I-L characteristics.

FIG. 15 is a graph indicating I-L characteristics of elements of Example 1, Comparative Example 1, and Comparative Example 2.

### MODE FOR CARRYING OUT THE INVENTION

An embodiment of an infrared LED element according to the present invention will be described with reference to the drawings. The following drawings are schematically illustrated, and the dimensional ratios in the drawings do not necessarily coincide with the actual dimensional ratios. Further, the dimensional ratios are not necessarily the same between the drawings.

In the present specification, the expression “a layer B is formed on or over a layer A” is intended to include a case in which the layer B is formed over a surface of the layer A with a thin film therebetween, as well as a case in which the layer B is formed directly on the surface of the layer A. The “thin film” referred to herein may indicate a layer having a film thickness of 50 nm or less and preferably a layer having a film thickness of 10 nm or less.

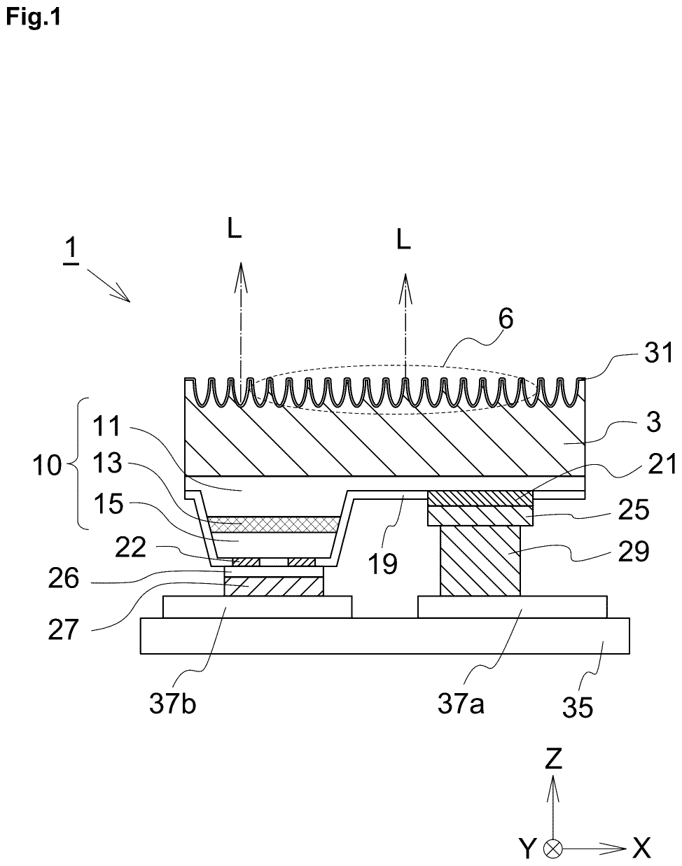

FIG. 1 is a cross-sectional view schematically illustrating a structure of an infrared LED element according to an embodiment of the present invention. As illustrated in FIG. 1, the infrared LED element 1 includes an InP substrate 3 and a semiconductor multilayer body 10 formed on or over the InP substrate 3. The infrared LED element 1 according to the present embodiment is mounted on a submount 35 with a flip-chip method. More specifically, the infrared LED element 1 is fixed to the submount 35 with a pattern electrode 37a and a pattern electrode 37b therebetween.

In the following description, an X-Y-Z coordinate system in which a principal surface of the InP substrate 3 is an XY plane and a normal direction with respect to the principal surface is a Z direction is appropriately referred to. Referring to this coordinate system, the infrared LED element 1 illustrated in FIG. 1 corresponds to a schematic cross-sectional view of the infrared LED element that is cut at a predetermined position along an XZ plane.

In the following description, positive and negative orientations distinguished from each other for directional expression will be described as a “+X direction” and a “−X direction” by adding positive and negative signs. In addition, a direction expressed without distinction between positive and negative orientations will be described simply as the “X direction”. That is, the mere expression of “X direction” used herein includes both “+X direction” and “−X direction”. The same applies to the Y direction and the Z direction. In the example of FIG. 1, the direction in which infrared light L is extracted from the infrared LED element 1 is the +Z direction.

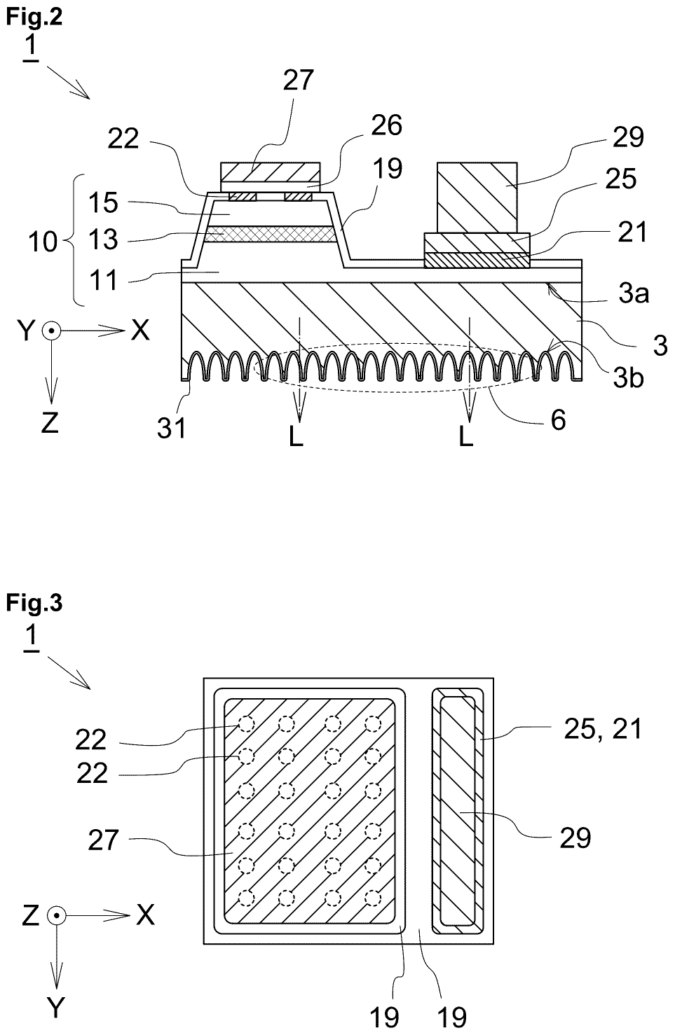

FIG. 2 is a cross-sectional view of the infrared LED element 1 from which the submount 35 and the pattern electrodes (37a and 37b) that are illustrated in FIG. 1 are removed. For convenience of description, the infrared LED element 1 illustrated in FIG. 2 is upside down with respect to FIG. 1. FIG. 3 is a schematic plan view of the infrared LED element 1 illustrated in FIG. 2 as viewed from the side opposite to the InP substrate 3, that is, in the −Z direction.

In the infrared LED element 1 according to the present embodiment, infrared light L generated in the semiconductor multilayer body 10 (more specifically, in an active layer 13 described later) is extracted from a side opposite to the submount 35, that is, from the InP substrate 3 side as illustrated in FIGS. 1 and 2. The infrared light L has a peak wavelength ranging from 1000 om to 1800 nm. [Structure]

The structure of the infrared LED element 1 will now be described in detail.

### (InP Substrate 3)

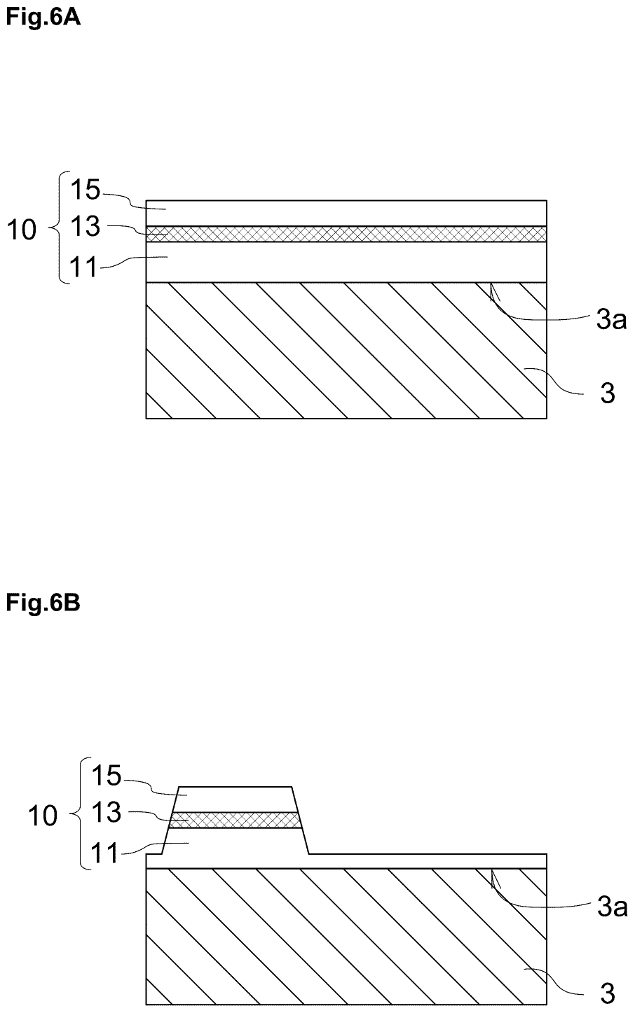

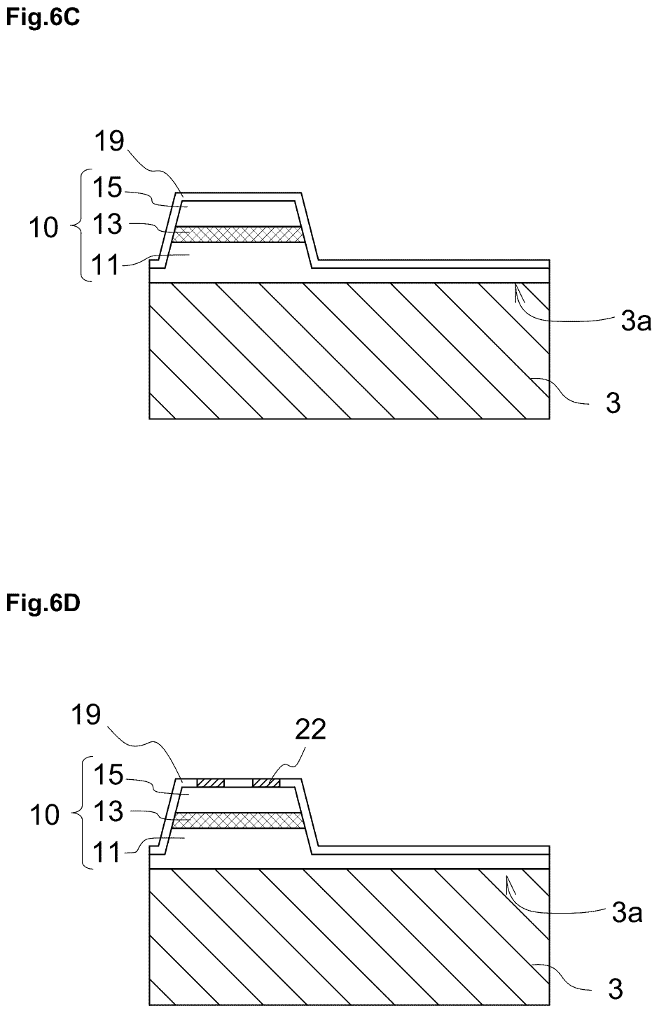

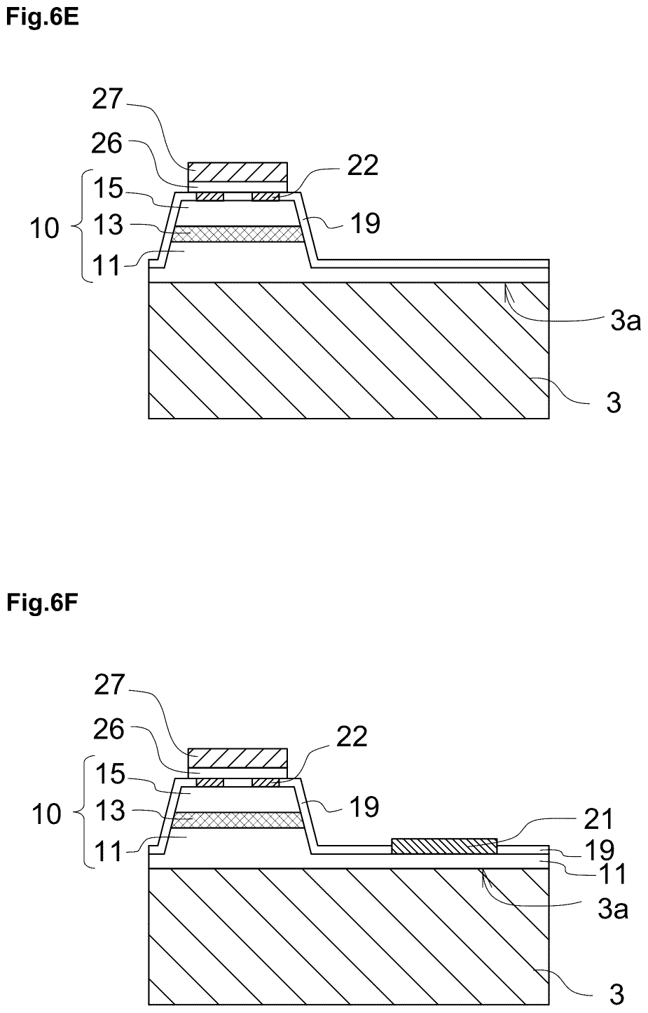

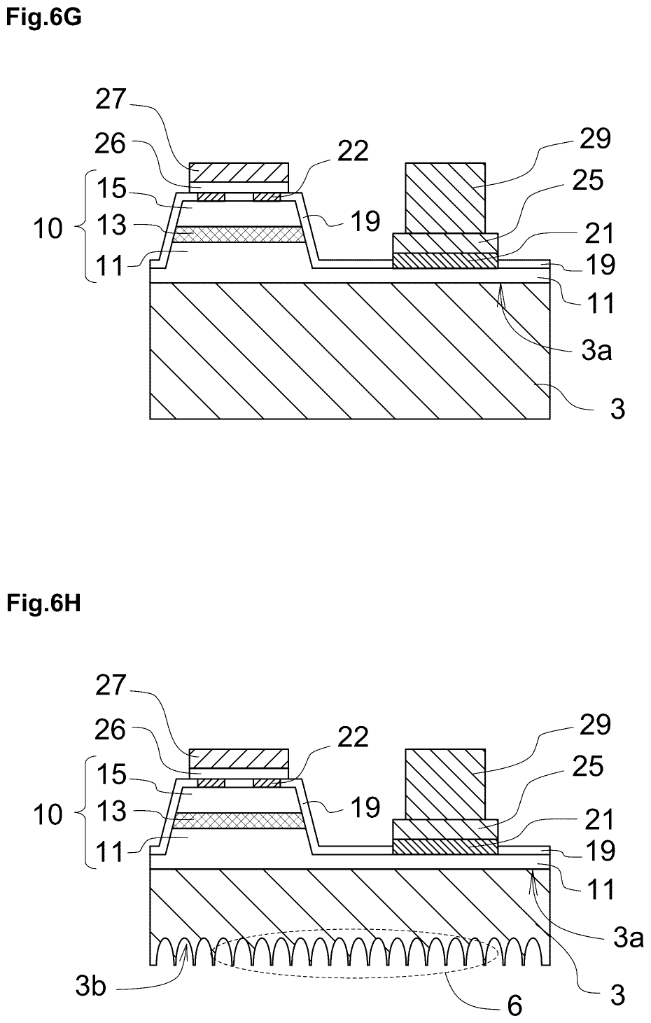

The infrared LED element 1 includes the InP substrate 3. The InP substrate 3 is also used as a growth substrate for growing the semiconductor multilayer body 10 as will be described later with reference to FIG. 6A. The InP substrate 3 preferably exhibits semi-insulating properties. Specifically, the InP substrate 3 has a resistivity of greater than or equal to 1×10⁶ Ω·cm and a carrier concentration of less than 1×10¹⁷/cm³.

As an example, the InP substrate 3 is doped with Fe at a carrier concentration of 1×10¹⁶/cm³ to 1×10¹⁷/cm³. Fe is a kind of transition metal that forms a deep level in InP. By doping such a transition metal at an extremely low concentration, the InP substrate 3 exhibits semi-insulating properties. Besides Fe, a metal such as W can be used as the transition metal that forms a deep level.

An undoped substrate may be used as the InP substrate 3. Even when the InP substrate 3 is undoped, impurities are inevitably added to the InP substrate 3 during a process of growing the semiconductor multilayer body 10 using the InP substrate 3 as a growth substrate, and thus, the InP substrate 3 is doped with impurities at a carrier concentration of less than 1×10¹⁷/cm³.

The thickness of the InP substrate 3 is preferably 20 μm to 1000 μm, and more preferably 50 μm to 700 μm.

As illustrated in FIG. 2, the semiconductor multilayer body 10 is disposed on or over a principal surface 3a (hereinafter referred to as “first principal surface 3a”) of principal surfaces of the InP substrate 3. The relief portion 6 is formed on the other principal surface 3b (hereinafter referred to as “second principal surface 3b”). In the infrared LED element 1 according to the present embodiment, a translucent layer 31 is formed along the shape of the relief portion 6 on the upper surface of the second principal surface 3b. The relief portion 6 and the translucent layer 31 will be described later.

### (Semiconductor Multilayer Body 10)

The infrared LED element 1 includes the semiconductor multilayer body 10 formed on or over the first principal surface 3a of the InP substrate 3. The semiconductor multilayer body 10 is a multilayer body of a plurality of semiconductor layers. Specifically, the semiconductor multilayer body 10 is formed by layering a first semiconductor layer 11, the active layer 13, and a second semiconductor layer 15 in this order from the side closer to the InP substrate 3.

In the present embodiment, the first semiconductor layer 11 is made of n-type InP. The thickness of the first semiconductor layer 11 is not limited, but is, for example. 1 μm to 20 μm, preferably 3 μm to 10 μm. The carrier concentration of the first semiconductor layer 11 is preferably 1×10¹⁷/cm³ to 5×10¹⁸/cm³, more preferably 5×10¹⁷/cm³ to 4×10¹⁸/cm³. Examples of an n-type dopant material included in the first semiconductor layer 11 include Sn, Si, S, Ge, and Se, and among others, Si is particularly preferable.

The first semiconductor layer 11 is formed substantially all over the first principal surface 3a of the InP substrate 3 as illustrated in FIG. 2.

The active layer 13 is a semiconductor layer formed on or over the first semiconductor layer 11 in the −Z direction. More specifically, the active layer 13 is formed on or over a part of the first semiconductor layer 11 as illustrated in FIG. 2.

A material for the active layer 13 is selected appropriately from ones that can generate light having a target wavelength and epitaxially grow by being lattice matched to the InP substrate 3. For instance, the active layer 13 may have a single-layer structure that includes GaInAsP. AlGaInAs, or InGaAs or may have a MQW (multiple quantum well) structure that includes a well layer made of GaInAsP, AlGaInAs, or InGaAs and a barrier layer made of GaInAsP, AlGaInAs, InGaAs, or InP that is greater in band gap energy than the well layer.

When having a single-layer structure, the active layer 13 has a film thickness of 50 nm to 2000 nm, preferably 100 nm to 500 nm. When having a MQW structure, the active layer 13 is formed by layering a well layer and a barrier layer, each of which has a film thickness of 5 nm to 20 nm, in the range of 2 cycles to 50 cycles.

The active layer 13 may be doped with an n-type or p-type dopant or may be undoped. When the active layer 13 is doped with an n-type dopant, the dopant may be, for example, Si.

The second semiconductor layer 15 is formed on or over the active layer 13 in the −Z direction. In the present embodiment, the second semiconductor layer 15 is a p-type semiconductor layer and includes a p-type cladding layer and a p-type contact layer.

The p-type cladding layer in the second semiconductor layer 15 is made of, for example, p-type InP. The thickness of the p-type cladding layer is not limited, but is, for example, 1 μm to 10 μm, preferably 2 μm to 5 μm. The carrier concentration of a p-type dopant in the p-type cladding layer at a position away from the active layer 13 is preferably 1×10¹⁷/cm³ to 3×10¹⁸/cm³, more preferably 5×10¹⁷/cm² to 3×10¹⁸/cm³.

The p-type contact layer in the second semiconductor layer 15 is made of, for example, p-type GaInAsP. The thickness of the p-type contact layer is not limited, but is, for example, 10 nm to 1000 nm, preferably 50 nm to 500 nm. The carrier concentration of a p-type dopant in the p-type contact layer is preferably 5×10¹⁷/cm³ to 3×10¹⁹/cm³, more preferably 1×10¹⁸/cm³ to 2×10¹⁹/cm³.

Examples of the p-type dopant material contained in the p-type cladding layer and the p-type contact layer that constitute the second semiconductor layer 15 include Zn, Mg, and Be. Among others, Zn or Mg is preferable, and Zn is particularly preferable.

A material for the first semiconductor layer 11 and the second semiconductor layer 15 is selected appropriately from ones that transmit the infrared light L generated in the active layer 13 and that can epitaxially grow by being lattice matched to the InP substrate 3. For instance, the first semiconductor layer 11 and the second semiconductor layer 15 can be made of a material such as GaInAsP and AlGaInAs, besides InP.

Although the present embodiment has described an example in which the second semiconductor layer 15 has a multilayer structure of the cladding layer and the contact layer, the present invention does not exclude a case where the cladding layer and the contact layer have a common material. Moreover, the present invention does not exclude a case where the first semiconductor layer 11 is a multilayer body including a cladding layer and a contact layer that are made of different materials.

### (First Electrode 21)

As described above, the active layer 13 is formed on or over a partial region of the first semiconductor layer 11. The infrared LED element 1 includes a first electrode 21 that is formed on or over a part of the first semiconductor layer 11 in a region in which the active layer 13 is not formed as illustrated in FIG. 2.

An ohmic connection is formed between the first electrode 21 and the first semiconductor layer 11. The first electrode 21 is made of, for example, a material such as Au/Ge/Au, Au/Ge/Ni/Au, AuGe, or AuGeNi, and may contain two or more of these materials. The thickness of the first electrode 21 is not limited, but is, for example, 50 nm to 500 nm, preferably 100 nm to 300 nm.

### (Insulating Layer 19)

As illustrated in FIG. 2, the infrared LED element 1 includes an insulating layer 19 formed so as to partly cover a side wall and an upper surface of the semiconductor multilayer body 10 in the −Z direction. The insulating layer 19 is made of an electrically-insulating material highly transparent to the infrared light L. Transmittance of the insulating layer 19 to the infrared light L is preferably 70% or higher, more preferably 80% or higher, and particularly preferably 90% or higher. On condition that the peak wavelength of the infrared light L ranges from 1000 nm to 1800 nm, the insulating layer 19 can be made of a material such as SiO₂, SiN, or Al₂O₃.

The film thickness of the insulating layer 19 is not limited, but is, for example, 50 nm to 5000 nm, preferably 100 nm to 1000 nm.

### (Second Electrode 22)

As illustrated in FIG. 2, the infrared LED element 1 includes a second electrode 22 formed on or over the second semiconductor layer 15 in the −Z direction. The second electrode 22 is disposed at a place apart from the first electrode 21 in a direction parallel to the principal surface of the InP substrate 3, that is, in a direction parallel to the XY plane (see FIG. 3 as well).

In the present embodiment, the second electrode 22 is constituted by partial electrodes discretely disposed on or over a part of the second semiconductor layer 15. More specifically, a plurality of partial electrodes of the second electrode 22 are discretely arranged on the XY plane as illustrated in FIG. 3. Actually, when the infrared LED element 1 is viewed from a side opposite to the InP substrate 3 (in the −Z direction), the second electrode 22 is hidden behind a second pad electrode 27, which is described later, and is invisible, but in FIG. 3, the second electrode 22 is indicated in a broken line in order to facilitate understanding.

The second electrode 22 is made of a material that allows an ohmic contact with the second semiconductor layer 15. The second electrode 22 is made of, for example, a material such as Au/Zn/Au, AuZn, or AuBe, and may contain two or more of these materials. When the second semiconductor layer 15 includes the contact layer as described above, an ohmic contact is formed between the contact layer and the second electrode 22. The thickness of the second electrode 22 is not limited, but is, for example. 50 nm to 500 nm, preferably 100 nm to 300 nm.

As illustrated in FIG. 2, the insulating layer 19 is formed on or over the second semiconductor layer 15 in the −Z direction in a region in which the second electrode 22 is not formed.

### (Reflective Electrode 26)

As illustrated in FIG. 2, the infrared LED element 1 according to the present embodiment includes a reflective electrode 26 on or over the second electrode 22 in the −Z direction. The reflective electrode 26 is also located on or over a part of the insulating layer 19. The reflective electrode 26 has a function of returning infrared light L which is included in infrared light L generated in the active layer 13, has traveled to the second semiconductor layer 15, and has passed through the insulating layer 19 toward the InP substrate 3. The reflective electrode 26 is made of an electrically conductive material having high reflectance to the infrared light L. The reflectance of the reflective electrode 26 to the infrared light Lis preferably 70% or higher, more preferably 80% or higher, and particularly preferably 90% or higher. When the peak wavelength of the infrared light L is 1000 nm to 1800 nm, the reflective electrode 26 can be made of a metallic material such as Ag, an Ag alloy, Au, Al. Al/Au, or Cu.

The thickness of the reflective electrode 26 is not particularly limited, but is, for example, 10 nm to 2000 nm, preferably 100 nm to 1000 nm.

The second electrode 22 needs to form an ohmic contact with the second semiconductor layer 15 and is thus made of a material that is readily alloyed together with the second semiconductor layer 15 (more specifically, the contact layer) to provide low contact resistance. From this viewpoint, AuZn, AuBe, Au/Zn/Au, etc. is used as the material of the second electrode 22 as described above. However, these materials have relatively low reflectance to the infrared light L. As a result, a proportion of the infrared light L to be absorbed by the second electrode 22 in the infrared light L that has been generated in the active layer 13 and that has traveled to the second semiconductor layer 15 may increase if the second electrode 22 is formed on an entire surface of the second semiconductor layer 15.

On the other hand, in the infrared LED element 1 according to the present embodiment, the partial electrodes of the second electrode 22 are discretely disposed on or over the second semiconductor layer 15, and the insulating layer 19 which is made of a material that has high transparency to the infrared light L is formed on or over the second semiconductor layer 15 in the region where the second electrode 22 is not formed. The reflective electrode 26 which is made of a material having higher reflectance to the infrared light L than the second electrode 22 is formed on or over the insulating layer 19. With this configuration, a part of the infrared light L that has been generated in the active layer 13 and that has traveled to the second semiconductor layer 15 travels through the insulating layer 19 without being absorbed by the second electrode 22, enters the reflective electrode 26, and then, is reflected by the reflective electrode 26 and is guided toward the InP substrate 3. Thus, the light extraction efficiency is enhanced. The reflective electrode 26 is not into contact with the second semiconductor layer 15 and thus does not need to be made of a material that can form an ohmic contact with the second semiconductor layer 15. Hence, the material of the reflective electrode 26 can be selected from metallic materials that are higher in reflectance than the material of the second electrode 22.

Note that the reflective electrode 26 may be integrated with the second pad electrode 27 described later.

### (First Pad Electrode 25, Second Pad Electrode 27)

As illustrated in FIGS. 1 to 3, the infrared LED element 1 includes a first pad electrode 25 formed on or over the first electrode 21 in the ˜Z direction and the second pad electrode 27 formed on or over the second electrode 22 in the −Z direction. Although FIGS. 1 and 2 illustrate a structure in which the second pad electrode 27 is formed on or over the reflective electrode 26, the second pad electrode 27 may also serve as the reflective electrode 26 if the second pad electrode 27 exhibits high reflectance to the infrared light L.

The first pad electrode 25 and the second pad electrode 27 each have a region for connection with a bonding wire. The first pad electrode 25 and the second pad electrode 27 are made of, for example, a material such as Ti/Au or Ti/Pt/Au. The thickness of each of the first pad electrode 25 and the second pad electrode 27 is not particularly limited, but ranges from 500 nm to 5000 nm, for example, and preferably ranges from 1000 nm to 4000 nm.

### (Height Adjustment Electrode 29)

As illustrated in FIGS. 1 to 3, the infrared LED element 1 includes a height adjustment electrode 29 formed on or over the first pad electrode 25 in the −Z direction. The height adjustment electrode 29 is provided to mount the infrared LED element 1 with a flip-chip method as illustrated in FIG. 1. As illustrated in FIGS. 1 and 2, the first pad electrode 25 is formed at a position (position on the +Z side) closer to the InP substrate 3 with respect to the second pad electrode 27. This causes a difference in level position (Z coordinate) between the first pad electrode 25 and the second pad electrode 27. When the infrared LED element 1 is mounted with a flip-chip method, it is necessary to ensure electrical connection between the pattern electrode 37a formed on the submount 35 and the first pad electrode 25 while forming electrical connection between the pattern electrode 37b formed on the submount 35 and the second pad electrode 27 as illustrated in FIG. 1.

With this in view, the height adjustment electrode 29 is formed to compensate for the difference in level between the first pad electrode 25 and the second pad electrode 27. The material for the height adjustment electrode 29 is not limited, but for example, Au plating. Ni plating, Cu plating, or the like can be used, and two or more kinds of these materials may be combined. However, from the viewpoint of oxidation resistance, it is preferred that at least a region of the height adjustment electrode 29 with a thickness of several tens nm to several hundreds nm in the vicinity of a surface thereof is plated with Au.

### (Relief Portion 6)

As described above, the InP substrate 3 included in the infrared LED element 1 is provided with the relief portion 6 on the second principal surface 3b side. The relief portion 6 has a structure having periodicity two-dimensionally in a direction parallel to the second principal surface 3b (that is, a direction along the XY plane).

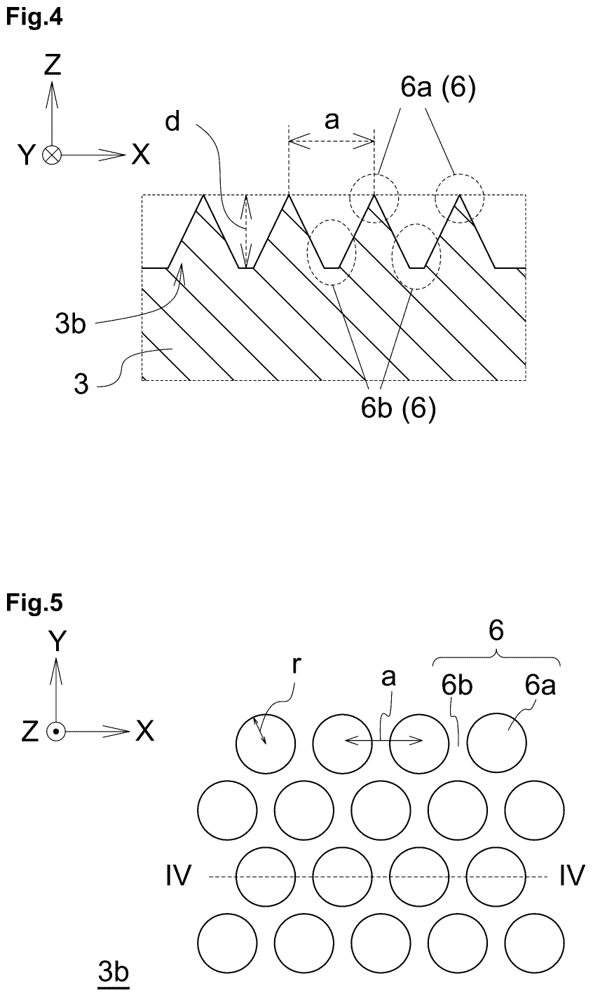

FIG. 4 is an enlarged view of a region of the InP substrate 3 illustrated in FIG. 1 where the relief portion 6 is formed. FIG. 5 is a schematic plan view when the surface (second principal surface 3b) of the InP substrate 3 on which the relief portion 6 is formed is viewed from the +Z side. FIG. 4 also corresponds to a cross-sectional view taken along line IV-IV in FIG. 5.

As illustrated in FIGS. 4 and 5, the relief portion 6 is formed by alternately repeating protrusions 6a and recesses 6b along the XY plane on the second principal surface 3b. That is, the plurality of protrusions 6a and the plurality of recesses 6b are regularly arranged on the XY plane. In the example illustrated in FIG. 5, the plurality of protrusions 6a is arranged in a triangular lattice shape. The recess 6b is formed between adjacent protrusions 6a.

The relief portion 6 is formed by regularly arranging the recess 6b having a depth d [μm] and the protrusion 6a adjacent to the recess 6b on the XY plane. When the distance between adjacent protrusions 6a or between adjacent recesses 6b, that is, a period length is defined as a [μm], the following Math Expressions (1) and (2) are preferably established between the period length a [μm] and the depth d [μm] of the recess 6b.

$$a > 7.2 \times ( λ / n ) \qquad ( 1 )$$

$$d > m \times ( a - 10 ) + 3.5 \qquad ( 2 )$$

In Math Expression (1), λ represents the peak wavelength of the infrared light L expressed in units of [μm]. Here, m is a dimensionless value defined by the following math expression.

$$m = - 1.02 \times ( λ / n ) = 0.602$$

More preferably, the following Math Expressions (3) and (4) are established between the period length a [μm] and the depth d [μm] of the recess 6b.

$$a > 10 \times ( λ / n ) \qquad ( 3 )$$

$$p \times ( a - 10 ) + 5. < d < q \times ( a - 8. ) + 8. \qquad ( 4 )$$

Here, p in Math Expression (3) and q in Math Expression (4) are dimensionless values defined by the following math expressions, respectively.

$$p = - 1.01 \times ( λ / n ) + 0.727$$

$$q = - 3.91 \times ( λ / n ) + 2.09$$

Since the relief portion 6 is formed to have regularity satisfying the above relational expressions, an amount of infrared light L extracted from the InP substrate 3 to the outside is increased, whereby the light extraction efficiency is enhanced. This respect will be described in detail later.

### (Translucent Layer 31)

The infrared LED element 1 according to the present embodiment has the translucent layer 31 formed along the shape of the relief portion 6 on the upper surface of the second principal surface 3b of the InP substrate 3 formed with the relief portion 6. The translucent layer 31 is made of a material having high transmittance to the infrared light L. The material for the translucent layer 31 is selected from ones that have a transmittance of 80% or higher to the infrared light L and a refractive index between refractive indexes of InP and the air. Specifically, the translucent layer 31 can be made of a material such as SiO₂, SiON, SIN, TiO₂, or MgO, or may be made of a combination of a plurality of kinds of these materials.

Since the infrared LED element 1 includes the translucent layer 31 having a refractive index between the refractive indexes of the air and InP, the proportion of the infrared light L totally reflected on the surface of the InP substrate 3 further decreases and the light extraction efficiency further improves. In particular, the refractive index of InP to the infrared light L with a wavelength of 1000 nm to 1800 nm is 3.1 to 3.3, and there is a large difference between the InP refractive index and the air refractive index (=1). Hence, due to the translucent layer 31 being provided on or over the InP substrate 3, the light extraction efficiency can be greatly increased.

### [Manufacturing Method]

An example of a method for manufacturing the infrared LED element 1 will be described with reference to FIGS. 6A to 6H. FIGS. 6A to 6H are each a cross-sectional view illustrating a step in the manufacturing process.

### (Step S1)

As illustrated in FIG. 6A, the InP substrate 3 as a growth substrate of the semiconductor multilayer body 10 is prepared. In the present embodiment, the InP substrate 3 having semi-insulating properties and doped with a transition metal forming a deep level such as Fe at a carrier concentration in the range of 1×10¹⁶/cm³ to 1×10¹⁷/cm³ is prepared. Note that, as the InP substrate 3, an undoped substrate may be used as described above. In one example, an Fe-doped InP substrate 3 that has a size of two inches and a thickness of 370 μm can be used.

### (Step S2)

The InP substrate 3 is conveyed into a MOCVD (metal organic chemical vapor deposition) apparatus, and the first semiconductor layer 11, the active layer 13, and the second semiconductor layer 15 are epitaxially grown in sequence on the first principal surface 3a (for example, (001) plane) of the InP substrate 3 to form the semiconductor multilayer body 10 (see FIG. 6A). In step S2, a type and a flow rate of a source gas, treatment time, environmental temperature, and other conditions are appropriately adjusted depending on the material or the film thickness of the layer to be grown. Examples of the materials for the semiconductor layers constituting the semiconductor multilayer body 10 are as described above.

The detailed example of the semiconductor multilayer body 10 is as follows. First, n-type InP doped with Si is layered on the first principal surface 3a of the InP substrate 3 with a predetermined film thickness (for example, about 8000 nm) to obtain the first semiconductor layer 11. Next. InGaAsP is layered with a film thickness of 300 nm to obtain the active layer 13. Here, the condition is such that the peak wavelength of the infrared light L emitted from the infrared LED element 1 is 1300 nm. However, as described above, the peak wavelength of the infrared light L can be adjusted within a range of 1000 nm to 1800 nm by adjusting the composition ratio of the materials constituting the active layer 13 or adopting the MQW structure.

Thereafter, p-type InP doped with Zn as a dopant is layered with a film thickness of 2800 nm to form a p-type cladding layer, and then p-type InGaAsP doped with Zn as a dopant is layered with a film thickness of 200 nm to form a p-type contact layer. The second semiconductor layer 15 is obtained by the p-type cladding layer and the p-type contact layer.

### (Step S3)

After the wafer including the semiconductor multilayer body 10 formed on the InP substrate 3 is taken out of the MOCVD apparatus, the second semiconductor layer 15 and the active layer 13 in a partial region are removed by etching as illustrated in FIG. 6B. As a result, a part of the first semiconductor layer 11 is exposed. Specifically, this step is performed, for example, by the following procedure.

First, a mask layer (SiO₂ layer in this example) is deposited with a predetermined film thickness (for example, about 2000 nm) on an upper surface of the second semiconductor layer 15, i.e., an outermost surface of the semiconductor multilayer body 10, by a plasma CVD method, and then a resist opening is formed in the mask layer using a photolithography method. Next, the mask layer inside the resist opening is etched and removed using buffered hydrofluoric acid, and then the resist is removed. Next, the semiconductor multilayer body 10 is etched by dry etching using Cl gas with the mask layer as a mask. As a result, the second semiconductor layer 15 and the active layer 13 in the partial region are removed. Note that, by this etching, a part of the first semiconductor layer 11 located below or under the active layer 13 (on the InP substrate 3 side) is also removed, but the first semiconductor layer 11 still remains on or over the InP substrate 3. Thereafter, the remaining mask layer is removed using buffered hydrofluoric acid.

### (Step S4)

The insulating layer 19 is formed on the entire surface of the semiconductor multilayer body 10 by a plasma CVD method as illustrated in FIG. 6C. As an example, the insulating layer 19 made of SiO₂ is formed with a film thickness of 200 nm.

### (Step S5)

The second electrode 22 is formed on or over a partial region of the second semiconductor layer 15 as illustrated in FIG. 6D. Specifically, this step is performed, for example, by the following procedure.

First, a resist opening is formed in some area of the insulating layer 19 using a photolithography method, and then the insulating layer 19 inside the resist opening is removed using buffered hydrofluoric acid. Next, a material (metallic material) constituting the second electrode 22 is deposited using an electron beam (EB) deposition apparatus. Next, after the resist is removed, the material film formed at a portion other than the region where the second electrode 22 is to be formed is lifted off. As an example, the second electrode 22 made of Au/Zn/Au is formed with film thickness of 25 nm/25 nm/150 nm.

After that, an annealing treatment is performed through a heating process, for example, at 450° C.′ for 10 minutes to form an ohmic contact between the second semiconductor layer 15 and the second electrode 22.

### (Step S6)

As illustrated in FIG. 6E, the reflective electrode 26 is formed on or over the second electrode 22, and further the second pad electrode 27 is formed on or over the reflective electrode 26. Specifically, this step is performed, for example, by the following procedure.

A resist opening is formed on or over the second electrode 22 using a photolithography method, and then a material film for the reflective electrode 26 and a material film for the second pad electrode 27 are deposited using the EB vapor deposition apparatus. The reflective electrode 26 and the second pad electrode 27 may be formed continuously. By depositing, for example, a multilayer body of Al/Au/Ti/Pt/Au, a multilayer structure including the reflective electrode 26 and the second pad electrode 27 is formed continuously. An example of the film thickness of the multilayer body is Al/Au/Ti/Pt/Au=5 nm/200 nm/50 nm/200 nm/1500 nm. Both Al and Au exhibit high reflectance to infrared light L having a wavelength of 1000 nm to 1800 nm.

### (Step S7)

As illustrated in FIG. 6F, the first electrode 21 is formed on or over the first semiconductor layer 11 at some place in the region in which the active layer 13 is not formed. Specifically, this step is performed, for example, by the following procedure.

First, a resist opening is formed in some area of the insulating layer 19 using a photolithography method, and then the insulating layer 19 inside the resist opening is removed using buffered hydrofluoric acid. Next, a material for forming the first electrode 21 is deposited using the EB deposition apparatus. Next, after the resist is removed, the material film formed at a portion other than the region where the first electrode 21 is to be formed is lifted off. As an example, the first electrode 21 made of Au/Ge/Au is formed with film thickness of 10 nm/30 nm/150 nm.

After that, an annealing treatment is performed through a heating process, for example, at 350° C. for 10 minutes to form an ohmic contact between the first semiconductor layer 11 and the first electrode 21.

### (Step S8)

As illustrated in FIG. 6G, the first pad electrode 25 is formed on or over the first electrode 21, and further the height adjustment electrode 29 is formed on or over the first pad electrode 25. Specifically, this step is performed, for example, by the following procedure.

A resist opening is formed on or over the first electrode 21 using a photolithography method, and then a material film for the first pad electrode 25 is deposited using the EB vapor deposition apparatus. As an example, the first pad electrode 25 made of Ti/Pt/Au is formed with film thickness of 50 nm/200 nm/1700 nm.

Next, a resist opening is formed on or over the first electrode 21 using a photolithography method, and then the height adjustment electrode 29 made of an Au plating is grown with a film thickness of, for example, 4000 nm on or over the first pad electrode 25 inside the resist opening using an electroless Au plating process. Thus, the height adjustment electrode 29 and the second pad electrode 27 are adjusted to a substantially equal level. The height adjustment electrode 29 may be grown using an electrolytic plating process or an EB vapor deposition technique. As a material of the height adjustment electrode 29, Ni plating or Cu plating less expensive than Au may be used. However, from the viewpoint of performing a mounting step later and from the viewpoint of enhancing the oxidation resistance, it is preferable that the height adjustment electrode 29 is formed by Au plating at least over a range of several tens nm to several hundreds nm from the uppermost surface.

### (Step S9)

The principal surface (second principal surface 3b) of the InP substrate 3 on the side opposite to the side on which the semiconductor multilayer body 10 is reduced in thickness. Specifically, this step is performed, for example, by the following procedure.

With the surface of the wafer on which the semiconductor multilayer body 10 is formed being fixed to a support member (not illustrated) using wax, etc., the InP substrate 3 is ground from the second principal surface 3b side by a single side polisher using a slurry solution and colloidal silica until the InP substrate 3 reaches a desired thickness (for example, 150 μm). After grinding, buffing is performed on the second principal surface 3b, so that the processed surface is finished into a mirror surface. Thereafter, abrasive grains are removed by an alkaline cleaning solution, and then the InP substrate 3 is taken off the support member and the wax is removed by cleaning. The grinding thickness can be appropriately adjusted, and is appropriately selected depending on the application and the subsequent process.

### (Step S10)

The relief portion 6 is formed on the second principal surface 3b of the InP substrate 3 (see FIG. 6H). Specifically, this step is performed, for example, by the following procedure.

SiO₂ is deposited with a predetermined film thickness (for example. 1000 nm) on the second principal surface 3b of the InP substrate 3 by a sputtering method. Next, a periodic resist pattern is formed in a direction parallel to the XY plane using a photolithography method. As an example, a resist pattern is formed by arranging a plurality of circles having a diameter of 6 μm in a triangular lattice shape with a period length of 8 μm.

Next, the resist pattern is transferred to the SiO₂ film by dry etching mainly using HF₃ gas, and then, the resist pattern is removed by plasma ashing mainly using O₂ gas.

Subsequently, the pattern formed on the SiO₂ film is transferred to the second principal surface 3b of the InP substrate 3 by dry etching mainly using SiCl₄ gas, Cl₂ gas, and Ar gas with the patterned SiO₂ film being used as an etching mask. At this time, the etching selectivity to the crystal plane of the InP substrate 3 is adjusted by adjusting a gas type used for dry etching, an etching condition, or the like, and as a result, the shape of the relief portion 6 of the InP substrate 3 obtained after etching is adjusted. Here, as an example, the relief portion 6 formed by arranging a plurality of triangular pyramid-shaped protrusions 6a having a diameter of 6 μm and a height of 6 μm in a triangular lattice shape at intervals of a period length of 8 μm is formed on the second principal surface 3b of the InP substrate 3. Note that the height of the protrusion 6a corresponds to the depth of the recess 6b (see FIG. 4).

### (Step S11)

Next, as illustrated in FIG. 2, the translucent layer 31 is deposited on the second principal surface 3b of the InP substrate 3 on which the relief portion 6 is formed using a plasma CVD method. In FIG. 2, the translucent layer 31 is formed along the shape of the relief portion 6. In other words, in FIG. 2, a surface relief similar to the relief portion 6 is also formed on the surface of the translucent layer 31. However, the surface of the translucent layer 31 may be flatter than that of the InP substrate 3. As an example, the translucent layer 31 made of SiO₂ is formed with a film thickness of 250 nm.

### (Step S12)

Next, the InP substrate 3 is formed into chips by blade dicing in a state of being attached to a dicing tape. Thereafter, the chipped piece is mounted on the submount 35 as illustrated in FIG. 1. More specifically, the submount 35 with the pattern electrode 37a and the pattern electrode 37b formed on an upper surface thereof is prepared, and then, the pattern electrode 37a and the height adjustment electrode 29 are bonded together and the pattern electrode 37b and the second pad electrode 27 are bonded together by ultrasonic waves. Thus, the flip-chip mounted infrared LED element 1 is manufactured.

### [Test 1]

A test was performed using simulation on the point that the value of the period length a of the relief portion 6 (see FIG. 4) and the value of the depth d of the recess 6b (see FIG. 4) affected an amount of the infrared light L extracted to the outside of the infrared LED element 1.

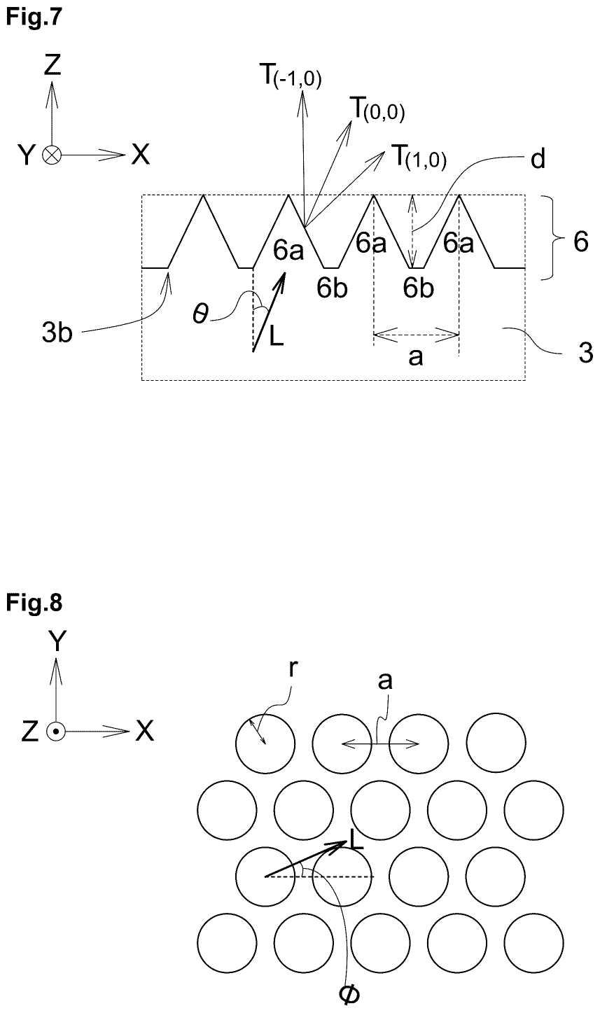

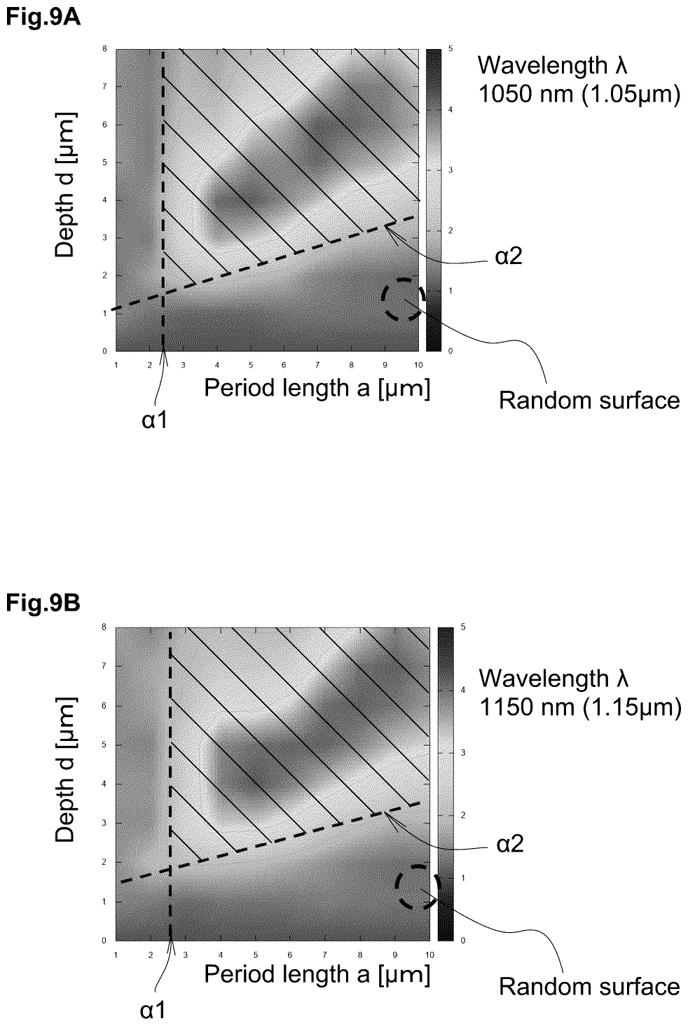

FIGS. 7 and 8 are diagrams for describing simulation conditions, and correspond to FIGS. 4 and 5, respectively.

The protrusion 6a was assumed to have a conical shape having a height d and a radius r. It was assumed that the relief portion 6 was formed on the second principal surface 3b of the InP substrate 3 by arranging a plurality of protrusions 6a having such a shape in a triangular lattice shape at intervals a. The height d of the protrusion 6a corresponds to the depth d of the recess 6b, and the interval a between the adjacent protrusions 6a is also an interval between the adjacent recesses 6b and corresponds to the period length. For simplicity of calculation, r=a/2 was set.

It was assumed that the infrared light L was incident at an incident angle (θ, φ) from the active layer 13 toward the relief portion 6. The incident angle θ is an angle of the infrared light L with respect to the Z axis in the traveling direction as illustrated in FIG. 7. The incident angle φ is an angle of the infrared light L with respect to the X axis in the traveling direction as illustrated in FIG. 8.

Under the conditions set as described above, transmittance T_{p,θ,φ}(i, j) which is the proportion of transmitted light subjected to (i, j)-th diffraction with respect to the incident light was calculated for a p-polarized component of the infrared light L incident on the relief portion 6 at the incident angle (θ, φ) by calculation processing based on a RCWA (rigorous coupled wave analysis) method for each wavelength). Note that i and j are both integers and indicate diffraction orders in the X direction and the Y direction, respectively. In the calculation processing, software Diffract MOD manufactured by RSoft was used.

In the calculation processing, it was assumed that there was no absorption of the infrared light L in the relief portion 6. That is, it was assumed that reflectance+transmittance=1.

The values of T_{p,θ,φ}(i, j) were calculated while 0 was changed in the range of 0° to 80° and φ was changed in the range of 0° to 30°. Since the arrangement shape of the plurality of protrusions 6a was assumed to be a triangular lattice shape as described above, calculation was performed using a value of φ within a range of 0° to 30° in consideration of symmetry, whereby the number of calculations can be reduced. Specifically, the values of T_{p,θ,φ}(i, j) are the same in the case of φ=20° and the case of φ=40°. On the other hand, regarding the value of θ, the calculation is impossible when θ reaches 90°, and thus, 80° was selected as the largest inclination angle by which the calculation was possible.

Next, transmittance T_{s,θ,φ}(i, j) which is the proportion of transmitted light subjected to (i, j)-th diffraction with respect to the incident light was calculated for the s-polarized component of the infrared light L incident on the relief portion 6 at the incident angle (θ, φ) by calculation processing based on the RCWA method for each wavelength λ in the same manner as for the p-polarized component.

For simplicity of calculation, it was assumed that the contributions of the p-polarized component and the s-polarized component were equal. At this time, the transmittance T(a, d) of the infrared light L incident on the relief portion 6 having the period length a and the height (depth of the recess 6b) d of the protrusion 6a can be calculated by following Math Expression (5) using the values of the transmittance T_{p,θ,φ}(i, j) related to the p-polarized component and the transmittance T_{s,θ,φ}(i, j) related to the s-polarized component.

$$\begin{matrix}[ Math 1 ] & \\ T ( a , d ) = {\int }_{θ , ϕ} {\sum }_{i , j} \frac{1}{2} ( {T}_{p , θ , ϕ} ( i , j ) + {T}_{s , θ , ϕ} ( i , j ) ) d θ d ϕ & ( 5 )\end{matrix}$$

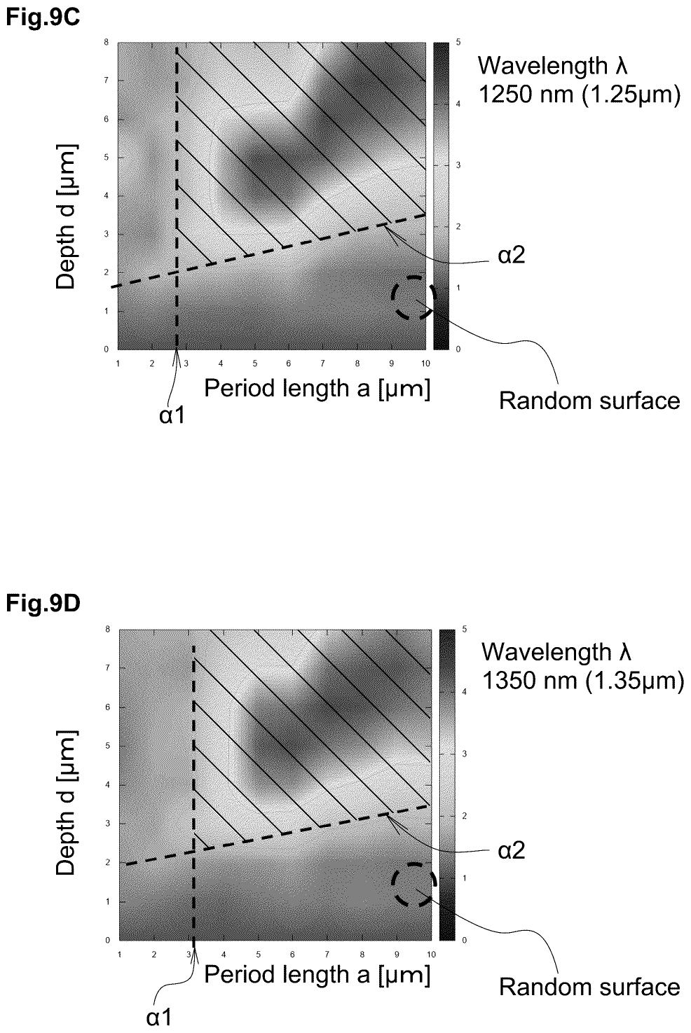

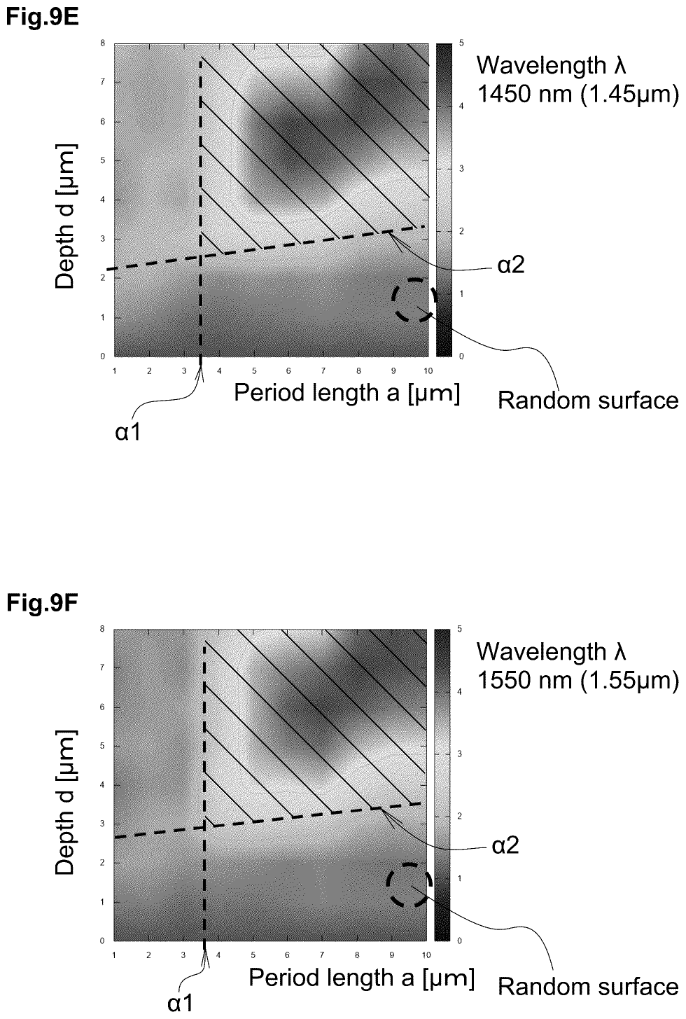

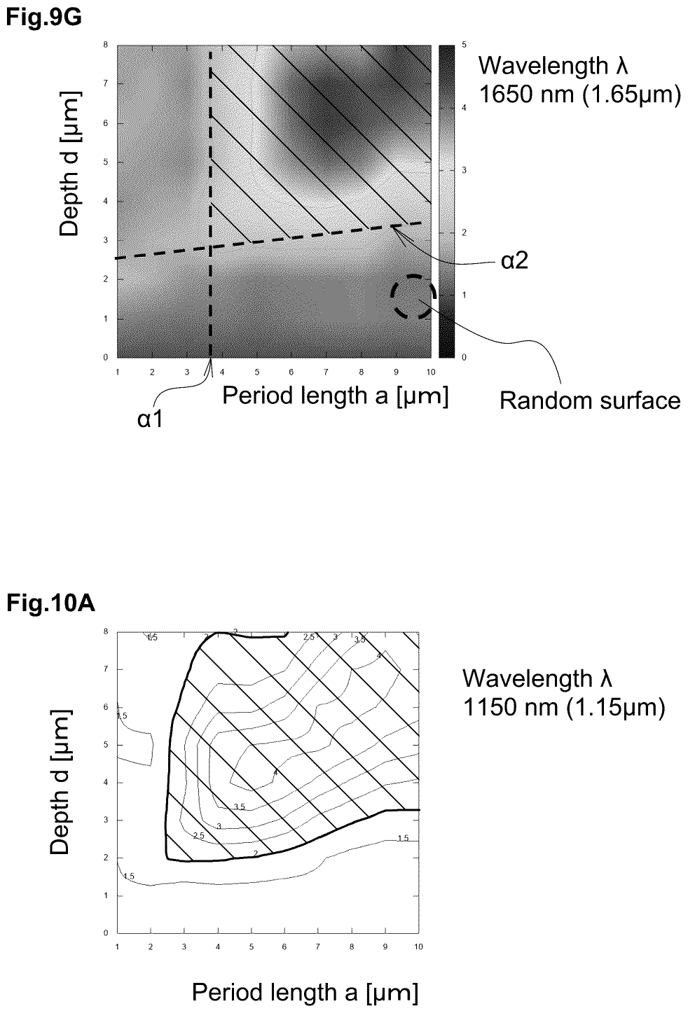

In the same manner, calculation processing based on the above Math Expression (5) was performed while changing the value of the period length a and the value of the height (depth of the recess 6b) d of the protrusion 6a by 1 μm. Then, the value of the transmittance T(a, d) obtained under the values of a and d was mapped on the two-dimensional coordinates as information for each wavelength λ. FIGS. 9A to 9G indicate the result.

In each of the graphs of FIGS. 9A to 9G, the horizontal axis represents the period length a [μm], and the vertical axis represents the depth d [μm] of the recess 6b. Each of the graphs indicates the calculation result by a relative value when d=0, that is, the value of the transmittance T(a, d) in a state where the relief portion 6 is not formed is set as a reference value (=1). In addition, seven values in total from 1050 nm (=1.05 μm) to 1650 nm (=1.65 μm) by 100 nm are used as the wavelength A of the infrared light L.

Meanwhile, when the principal surface of the InP substrate 3 is physically polished, a random rough surface is formed on the principal surface of the InP substrate 3. When this rough surface was observed with a laser microscope, the depth of the surface relief was 1 μm to 2 μm. Further, when height information of the obtained rough surface for each position in the planar direction was subjected to two-dimensional Fourier transform, it was confirmed that the main period length was 15 μm to 30 μm.

The graphs of FIGS. 9A to 9G only indicate a range in which the period length a is 1 μm to 10 μm. However, in any of the graphs of FIGS. 9A to 9G, the value of the transmittance T(a, d) is not greatly affected by the value of the period length a, and the transmittance T(a, d) is kept low at substantially the same value within a range where the depth d is in the range of 1 μm to 2 μm. For this reason, the graphs of FIGS. 9A to 9G indicate, as a range of a random rough surface, a region having a period length a of about 10 μm and a depth d of 1 μm to 2 μm in a broken line circle for reference.

It can be seen from the results of FIGS. 9A to 9G that, when a random rough surface is formed on the second principal surface 3b of the InP substrate 3, the value of the transmittance T(a, d) of the infrared light L is not greatly changed as compared with the case of d=0 in which there is no surface relief. In addition, it is confirmed from the results of FIGS. 9A to 9G that the value of the transmittance T(a, d) of the infrared light L is high depending on the values of the period length a and the depth d of the recess 6b.

More specifically, it can be concluded that, in the graphs of FIGS. 9A to 9G, when the relief portion 6 is formed under the condition that the transmittance T(a, d) of the infrared light L is twice or more the transmittance when d=0 that means there is no surface relief, the extraction efficiency of the infrared light L is sufficiently improved as compared with the case where a random rough surface is simply provided on the second principal surface 3b of the InP substrate 3. Further, it can be concluded that, when the relief portion 6 is formed under the condition that the transmittance T(a, d) of the infrared light L is three times or more the transmittance when d=0, the extraction efficiency of the infrared light L is significantly improved as compared with the case where a random rough surface is simply provided on the second principal surface 3b of the InP substrate 3.

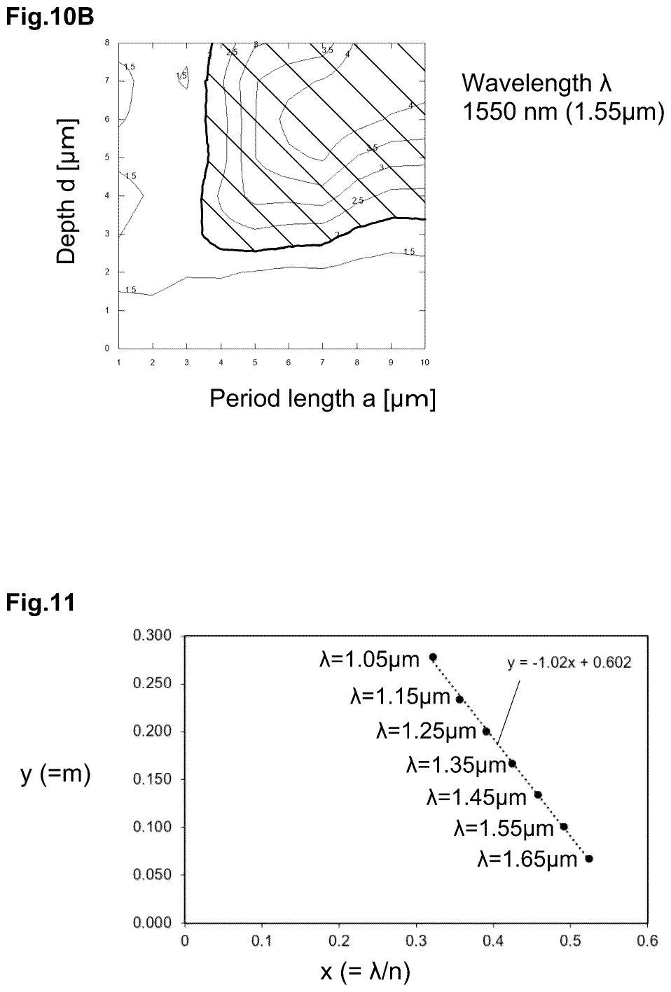

FIG. 10A is a graph illustrating a two-dimensional mapping result of transmittance T(a, d) in a case where the wavelength λ of infrared light Lis 1150 nm, that is, the result of FIG. 9B, as a contour chart. Similarly, FIG. 10B is a graph illustrating a two-dimensional mapping result of transmittance T(a, d) in a case where the wavelength % of infrared light L is 1550 nm, that is, the result of FIG. 9F, as a contour chart. Note that, in both graphs, a line indicating T(a, d)=2 is indicated in a thick line and a region of T(a, d)>2 is hatched in order that the graphs are easy to view.

It can be seen from FIGS. 10A and 10B that the region indicating T(a, d)>2 can be approximated to a region surrounded by a total of two lines (hereinafter referred to as “pseudo boundary lines”) that are a straight line parallel to the vertical axis and an upward-sloping straight line. As can be seen from FIGS. 9A to 9G, even in other cases where the value of the wavelength λ is different, the region indicating T(a, d)>2 can be similarly approximated to a region surrounded by a pseudo boundary line α1 parallel to the vertical axis and an upward-sloping pseudo boundary line α2.

However, it is confirmed that the two pseudo boundary lines (α1, α2) are expressed by different linear expressions according to the wavelength λ as a result of the detailed analysis of the results illustrated in FIGS. 9A to 9G. Then, it is confirmed as a result of the approximation calculation that the two pseudo boundary lines α1 and α2 are expressed as follows at any wavelength λ.

$$α 1 : a = 7.2 \times ( λ / n ) \qquad ( 1 a )$$

$$α 2 : d = m ( a - 10 ) + 3.5 \qquad ( 2 a )$$

Note that n is a value of the refractive index of the InP substrate 3 with respect to the infrared light L having the wavelength λ, and is within a range of 3.1 to 3.3.

Note that the inclination of the pseudo boundary line α2 non-parallel to the vertical axis is different for each wavelength λ of the infrared light L, and it is confirmed that the inclination m can be approximated as m=−1.02×(λ/n)+0.602. FIG. 11 is a graph indicating an approximate curve from the result of plotting values of m and values of (λ/n) for each wavelength λ of the infrared light L. It is confirmed from FIG. 11 that m can be approximated as m=−1.02×(λ/n)+0.602.

In FIGS. 9A to 9G, the region surrounded by the pseudo boundary line α1 represented by Math Expression (1a) described above and the pseudo boundary line α2 represented by Math Expression (2a) is hatched. Within this region, the transmittance satisfies T(α, d)>2 at any wavelength λ, and corresponds to a region where the light transmittance is greatly increased as compared with a case where the relief portion 6 is not formed on the second principal surface 3b of the InP substrate 3 or a case where a random rough surface is formed.

In other words, it can be seen that an amount of infrared light L extracted from the InP substrate 3 can be greatly increased by forming the relief portion 6 having periodicity satisfying

$$a > 7.2 \times ( λ / n ) \qquad ( 1 )$$

$$d > m \times ( a - 10 ) + 3.5 \qquad ( 2 )$$

in terms of the period length a [μm] and the depth d [μm] of the recess 6b on the second principal surface 3b of the InP substrate 3. In Math Expression (2), the value of m satisfies m=−1.02×(λ/n)+0.602 as described above.

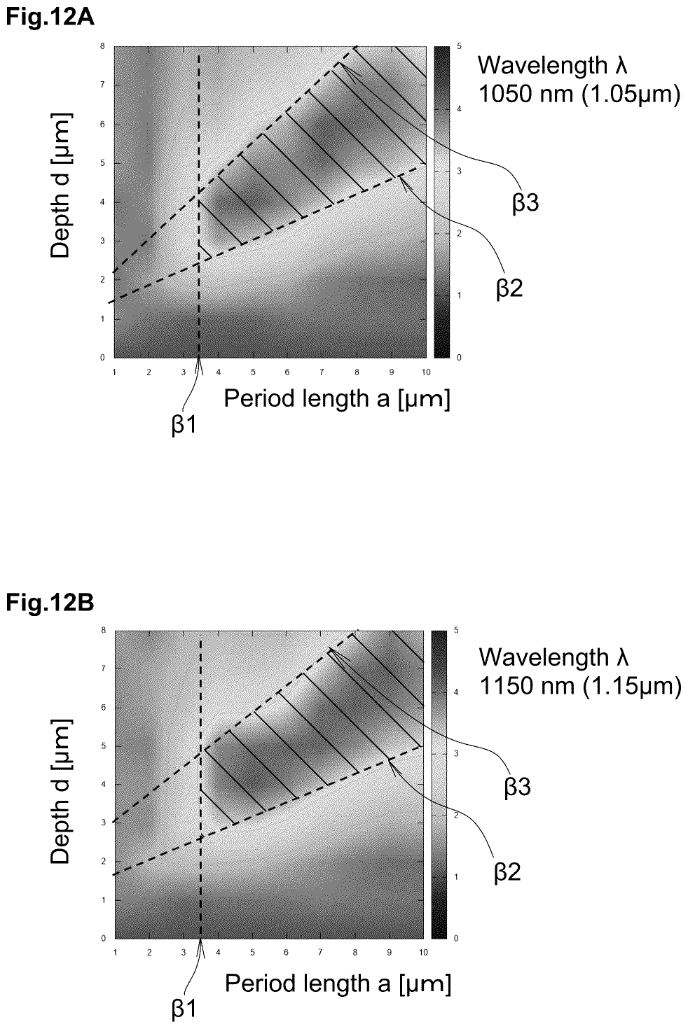

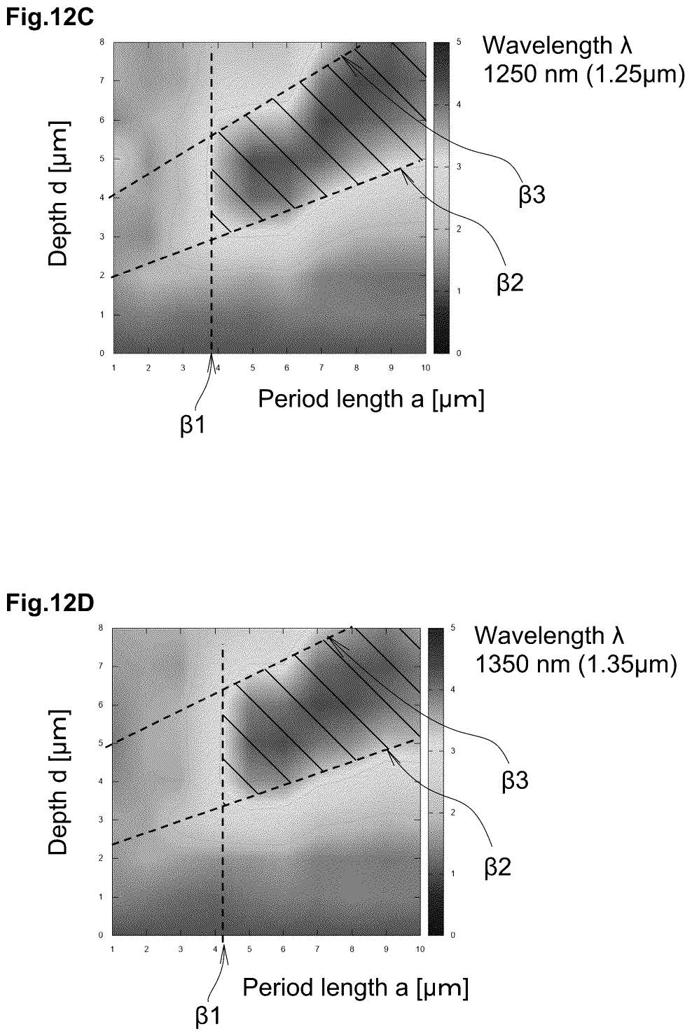

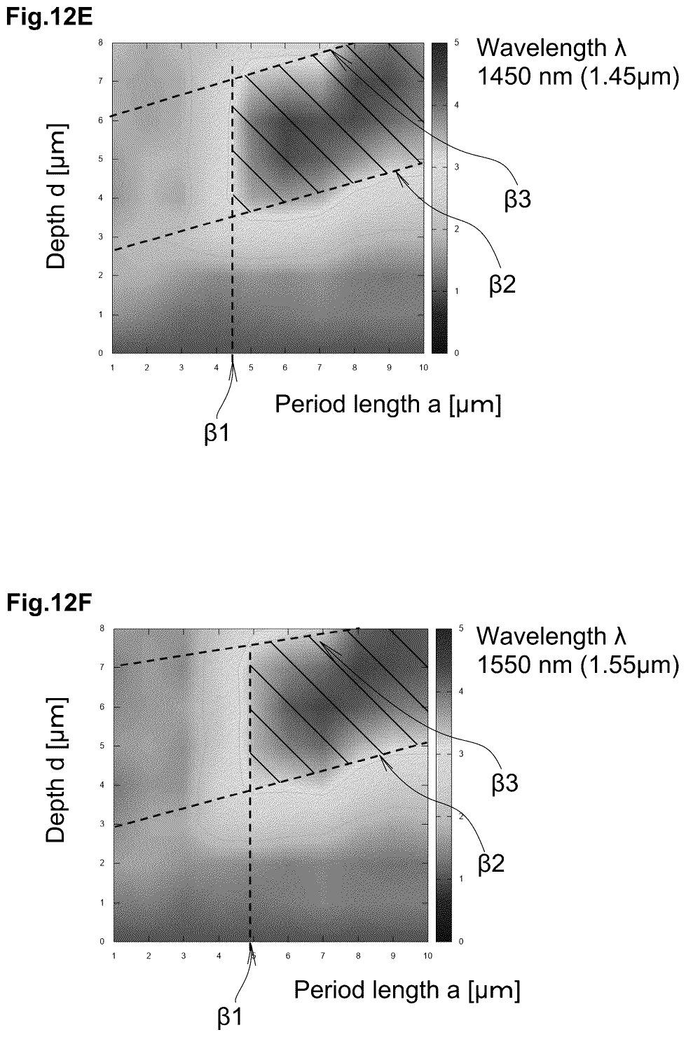

According to a similar test, it can be seen that the region indicating T(α, d)>3 can be approximated to a region surrounded by a pseudo boundary line β1 parallel to the vertical axis, an upward-sloping pseudo boundary line β2, and an upward-sloping pseudo boundary line β3. FIGS. 12A to 12G are graphs obtained by superimposing pseudo boundary lines (β1, β2, β3) defined by expressions to be described later on two-dimensional mapped graphs like FIGS. 9A to 9G.

As a result of the detailed analysis of the two-dimensional mapping, it is confirmed that the three pseudo boundary lines (β1, β2, and β3) are expressed by different linear expressions according to the wavelength λ. Then, it is confirmed as a result of the approximation calculation that the three pseudo boundary lines β1, β2, and β3 are expressed as follows at any wavelength λ.

$$β 1 : a = 10 \times ( λ / n ) \qquad ( 3 a )$$

$$β 2 : d = p \times ( a - 10 ) + 5. \qquad ( 4 a )$$

$$β 3 : d = q \times ( a - 8. ) + 8. \qquad ( 4 b )$$

Note that n is a value of the refractive index of the InP substrate 3 with respect to the infrared light L having the wavelength λ, and is within a range of 3.1 to 3.3, as described above.

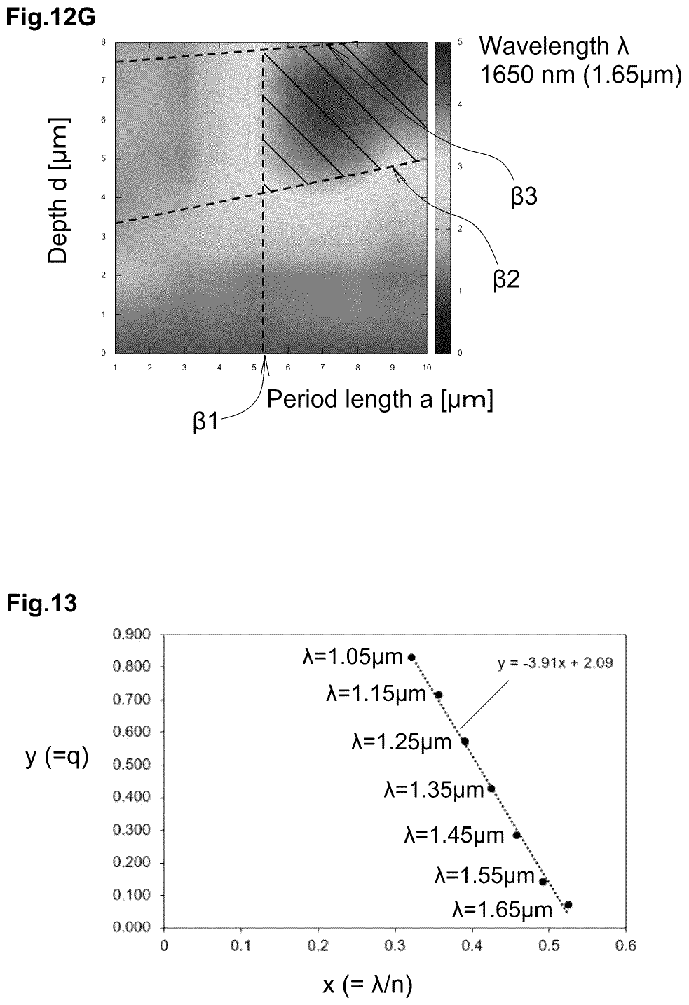

Note that the inclination of the pseudo boundary line β2 non-parallel to the vertical axis is different for each wavelength λ of the infrared light L, and it is confirmed that the inclination p can be approximated as p=−1.01×(λ/n)+0.727. Similarly, the inclination of the pseudo boundary line β3 non-parallel to the vertical axis is different for each wavelength λ of the infrared light L, and it is confirmed that the inclination q can be approximated as q=−3.91×(λ/n)+2.09. FIG. 13 is a graph indicating an approximate curve from the result of plotting values of q and values of (λ/n) for each wavelength λ of the infrared light L. It is confirmed from FIG. 13 that q can be approximated as q=−3.91×(λ/n)+2.09. It can be seen that the inclination p of the pseudo boundary line 2 can also be approximated in the similar manner, although the description thereof will be omitted from the viewpoint of avoiding redundant description.

In FIGS. 12A to 12G, the region surrounded by the pseudo boundary line β1 represented by above Math Expression (3a), the pseudo boundary line β2 represented by Math Expression (4a), and the pseudo boundary line β3 represented by Math Expression (4b) is hatched. Within this region, the transmittance satisfies T(α, d)>3 at any wavelength λ, and corresponds to a region where the light transmittance is so greatly increased as compared with a case where the relief portion 6 is not formed on the second principal surface 3b of the InP substrate 3 or a case where a random rough surface is formed.

In other words, it can be seen that an amount of infrared light L extracted from the InP substrate 3 can be greatly increased by forming the relief portion 6 having periodicity satisfying

$$a > 10 \times ( λ / n ) \qquad ( 3 )$$

$$p \times ( a - 10 ) + 5. < d < q \times ( a - 8. ) + 8. \qquad ( 4 )$$

in terms of the period length a [μm] and the depth d [μm] of the recess 6b on the second principal surface 3b of the InP substrate 3. In Math Expression (4), the values of p and q are p=−1.01×(λ/n)+0.727 and q=−3.91×(λ/n)+2.09, respectively, as described above.

The present inventor considers as follows as the reason why the transmittance of the infrared light L cannot be increased so much when a random rough surface is formed on the second principal surface 3b of the InP substrate 3. The diffraction of the infrared light L progresses in the depth direction (Z direction). Therefore, if the depth d is insufficient, high order diffraction does not sufficiently occur. That is, in a case where the depth d of a recess is as shallow as about 1 μm to 2 μm like a random rough surface, it is considered that the incident light is diffracted by passing through the rough surface, but the diffracted light is reflected without being transmitted.

Conversely, by providing the relief portion 6 formed by periodically arranging protrusions and recesses on the second principal surface 3b of the InP substrate 3 with the recesses 6b having a certain depth, it is possible to generate and extract high-order diffracted light. Therefore, the present invention is not limited to the “shape” of the relief portion 6.

In the above simulation, the calculation is performed assuming that the protrusion 6a has a conical shape. On the other hand, when the shape of the protrusion 6a was changed to a cylindrical shape, a truncated cone shape, a quadrangular pyramid shape, and a quadrangular pyramid shape and the same test was performed, no change was found in the overall trend, although the value of the transmittance changed. In addition, when the test was performed with the periodic structure being set as a square lattice, no change was also found in the overall trend. This result is also in line with the above consideration. From this viewpoint, it is predicted that a similar conclusion can also be obtained when the arrangement shape of the relief portion 6 is set as a rectangular lattice shape or an isosceles triangular lattice shape, although additional test by simulation has not been performed.

### [Test 2]

Infrared LED elements were manufactured in the same manner except for the surface state of the second principal surface 3b of the InP substrate 3, and current-light output characteristics (I-L characteristics) of the manufactured infrared LED elements were compared.

### Example 1

The infrared LED element 1 manufactured through steps S1 to S12 was used as an element of Example 1. In the element of Example 1, the relief portion 6 included protrusions 6a and recesses 6b that were arranged in a triangular lattice shape, and had a period length a of 8 μm, and a depth d of the recess 6b of 6 μm.

### Comparative Example 1

An infrared LED element manufactured in the same manner as in Example 1 except that step S10 was not performed was used as an element of Comparative Example 1. In the element of Comparative Example 1, the second principal surface 3b of the InP substrate 3 was substantially flat without having a surface relief.

### Comparative Example 2

An infrared LED element manufactured in the same manner as in Example 1 except that mirror finish was not performed after the polishing processing in step S9 and step S10 was not performed was used as an element of Comparative Example 2. In the element of Comparative Example 2, the second principal surface 3b of the InP substrate 3 had a random rough surface having an arithmetic average roughness Ra of 0.36 μm or less and a maximum height of 2 μm or less.

### (Measurement Method)

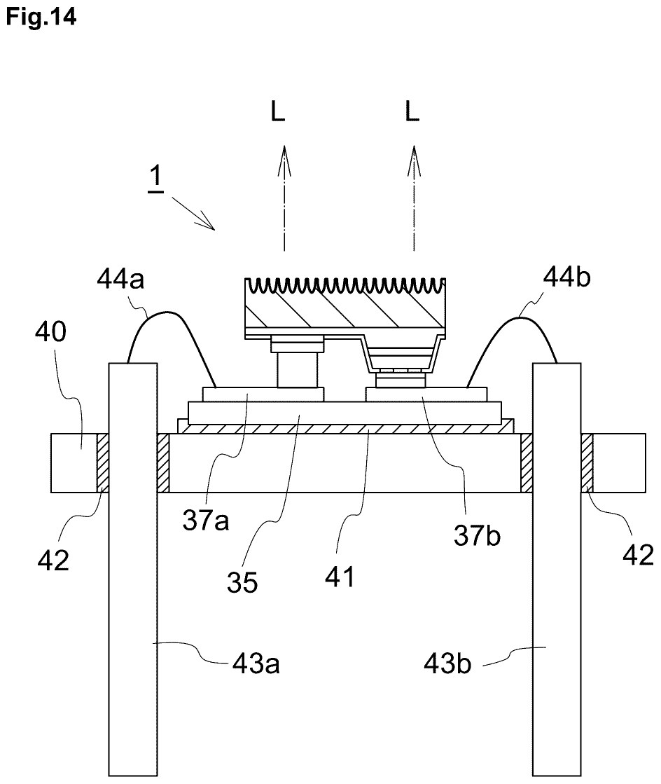

The elements of Example 1, Comparative Example 1, and Comparative Example 2 were each mounted on a stem 40 as illustrated in FIG. 14, and an electric current was supplied from a power source (not illustrated) to allow the elements to emit light. Then, the relationship between an amount of electric current and the light output at this time was plotted. The light output was measured using an integrating sphere method on the basis of the amount of infrared light L received by a light receiving sensor. FIG. 14 illustrates a state in which the infrared LED element 1 corresponding to the element of Example 1 is mounted on the stem 40.

A specific structure of the stem 40 illustrated in FIG. 14 will be described. A pair of feeder pins (43a, 43b) that is electrically insulated from each other by insulating members 42 is inserted in the stem 40. The submount 35 of the infrared LED element I is fixed to an upper surface of the stem 40 by silver paste 41. The feeder pin 43a and the pattern electrode 37a are connected to each other by a bonding wire 44a, and the feeder pin 43b and the pattern electrode 37b are connected to each other by a bonding wire 44b.

### (Results)

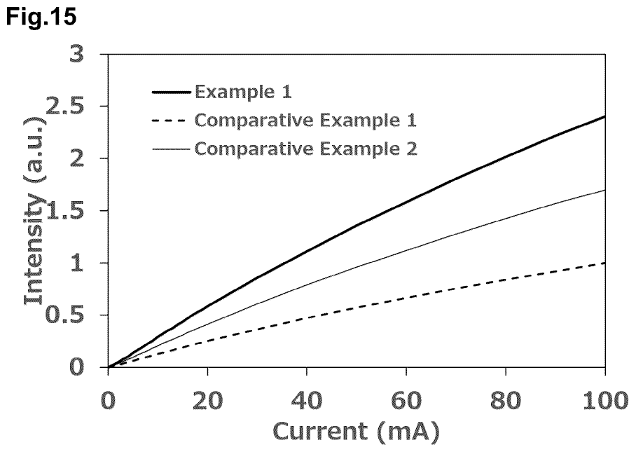

FIG. 15 is a graph showing I-L characteristics of the elements of Example I. Comparative Example 1, and Comparative Example 2. In FIG. 15, the horizontal axis represents an amount of supplied electric current, and the vertical axis represents light output. As illustrated in FIG. 15, the element of Example I has light extraction efficiency which is improved about two or four times as compared with the element of Comparative Example 1. In addition, the light extraction efficiency was improved about 1.8 times as compared with the element of Comparative Example 2.

### OTHER EMBODIMENTS

Other embodiments will now be described.
<1> Although the infrared LED element 1 includes the translucent layer 31 on the light extraction surface side (second principal surface 3b side) of the InP substrate 3 in the embodiment described above, the infrared LED element 1 may or may not include the translucent layer 31 in the present invention. However, from the viewpoint of improving the light extraction efficiency, the infrared LED element 1 preferably includes the translucent layer 31.
<2> Although the second electrode 22 is constituted by partial electrodes in the embodiment described above, the second electrode 22 may or may not be constituted by partial electrodes in the present invention. However, from the viewpoint of improving the light extraction efficiency, it is preferable that the second electrode 22 is constituted by partial electrodes and the infrared LED element 1 includes the reflective electrode 26 on or over the second electrode 22.

Note that, in the present invention, the infrared LED element 1 may or may not include the reflective electrode 26.
<3> Although the first semiconductor layer 11 is of an n-type and the second semiconductor layer 15 is of a p-type in the embodiment described above, the conductivity types may be inverted.
<4> The order of some steps among the steps of the manufacturing method described above may be changed. For instance, step S5 for forming the second electrode 22 and step S7 for forming the first electrode 21 may be switched in order. Further, step S9 for reducing the thickness of the InP substrate 3 may be performed prior to the steps for forming the electrodes (21, 22).
<5> Although the above embodiment has described an example in which the InP substrate 3 exhibits semi-insulating properties or insulating properties, the present invention does not exclude a case where the InP substrate 3 exhibits conductivity.

### DESCRIPTION OF REFERENCE SIGNS

1 Infrared LED element
3 InP substrate
3a First principal surface of InP substrate
3b Second principal surface of InP substrate
6 Relief portion
6a Protrusion
6b Recess
10 Semiconductor layer
11 First semiconductor layer
13 Active layer
15 Second semiconductor layer
19 Insulating layer
21 First electrode
22 Second electrode
25 First pad electrode
26 Reflective electrode
27 Second pad electrode
29 Height adjustment electrode
31 Translucent layer
35 Submount
37a Pattern electrode
37b Pattern electrode
40 Stem
41 Silver paste
42 Insulating member
43a Feeder pin
43b Feeder pin
44a Bonding wire
44b Bonding wire
L Infrared light

1. An infrared LED element having a peak emission wavelength in a range from 1000 nm to 1800 nm, the infrared LED element comprising:
an indium phosphide (InP) substrate that has a first principal surface and a second principal surface which are a pair of principal surfaces facing each other;
a first semiconductor layer of a p-type or an n-type, the first semiconductor layer being formed on or over the first principal surface of the InP substrate;
an active layer formed on or over the first semiconductor layer;
a second semiconductor layer of a conductivity type different from the conductivity type of the first semiconductor layer, the second semiconductor layer being formed on or over the active layer;
a first electrode formed on or over the first semiconductor layer in a region in which the active layer is not formed;
a second electrode formed on or over the second semiconductor layer at a position apart from the first electrode in a direction parallel to the first principal surface of the InP substrate; and
a relief portion formed on the second principal surface of the InP substrate and having periodicity in a direction parallel to the second principal surface.

2. The infrared LED element according to claim 1, wherein the relief portion satisfies Math Expression (1) and Math Expression (2) where the peak emission wavelength is λ [μm], a refractive index of the InP substrate is n, a period length which is a distance between adjacent protrusions or recesses is a [μm], and a depth of the recess is d [μm],
$$a > 7.2 \times ( λ / n ) \qquad ( 1 )$$
$$d > m \times ( a - 10 ) + 3.5 \qquad ( 2 )$$
where m is a dimensionless value defined by a following math expression.
$$m = - 1.02 \times ( λ / n ) + 0.602$$

3. The infrared LED element according to claim 2, wherein the period length a [μm] and the depth d [μm] satisfy Math Expressions (3) and (4),
$$a > 10 \times ( λ / n ) \qquad ( 3 )$$
$$p \times ( a - 10 ) + 5. < d < q \times ( a - 8. ) + 8. \qquad ( 4 )$$
where p and q are dimensionless values defined by following math expressions, respectively.
$$p = - 1.01 \times ( λ / n ) + 0 \text{.727}$$
$$q = - 3.91 \times ( λ / n ) + 2.09$$

4. The infrared LED element according to claim 1, further comprising a translucent layer on an upper surface of the relief portion, the translucent layer being made of a material that exhibits transparency to infrared light emitted from the active layer and that has a refractive index between a refractive index of a material constituting the InP substrate and a refractive index of air.

5. The infrared LED element according to claim 1, wherein the InP substrate is doped with Fe.

6. The infrared LED element according to claim 2, further comprising a translucent layer on an upper surface of the relief portion, the translucent layer being made of a material that exhibits transparency to infrared light emitted from the active layer and that has a refractive index between a refractive index of a material constituting the InP substrate and a refractive index of air.

7. The infrared LED element according to claim 3, further comprising a translucent layer on an upper surface of the relief portion, the translucent layer being made of a material that exhibits transparency to infrared light emitted from the active layer and that has a refractive index between a refractive index of a material constituting the InP substrate and a refractive index of air.

8. The infrared LED element according to claim 2, wherein the InP substrate is doped with Fe.

9. The infrared LED element according to claim 3, wherein the InP substrate is doped with Fe.
